(19) United States
(12) Patent Application Publication
(10) Pub. No.: US 2020/0327261 A1
(43) Pub. Date: Oct. 15, 2020

(54) Building Material Estimation System, Management Server thereof, and Building Material Estimation Method

(71) Applicant: Sbuild Co., Ltd., Osaka-shi (JP)

(72) Inventors: Takaichi SAWAGUCHI, Suita-shi (JP); Takahiro ISHIKAWA, Wako-shi (JP); Taiki HORINO, Tokyo (JP)

(21) Appl. No.: 16/721,990

(22) Filed: Dec. 20, 2019

(30) Foreign Application Priority Data
Apr. 10, 2019 (JP) 2019-074677
Aug. 30, 2019 (JP) 2019-158269
Sep. 3, 2019 (JP) 2019-160283
Sep. 3, 2019 (JP) 2019-160286

(51) Int. Cl. G06F 30/13; G06Q 50/08

(52) U.S. Cl. CPC G06F 30/13; G06Q 50/08

(57) ABSTRACT

There are provided a building material estimation system and a building material estimation method, which can accurately determine the required number of building materials. According to the building material group, the construction area, and the arrangement avoidance area unfolded in the memory, the number of constructions of the building materials which at least overlap partially in the construction area and the number of avoidances of the building materials included completely in the arrangement avoidance area are determined, and the number of avoidances is subtracted from the number of constructions, by which the number of building materials constituting the building material group in the building material arrangement diagram is obtained.

### CROSS REFERENCE TO RELATED APPLICATION

The present application claims priority from Japanese Patent Applications No. 2019-074677 filed on Apr. 10, 2019, No. 2019-158269 filed on Aug. 30, 2019, No. 2019-160283 filed on Sep. 3, 2019, No. 2019-160286 filed on Sep. 3, 2019, the disclosures of which are herein incorporated by reference in its entirety.

### BACKGROUND OF THE INVENTION

### 1. Field of Invention

The present invention relates to a building material estimation system a management server thereof, and a building material estimation method for obtaining a required number of building materials such as tiles and panels to be allocated to a ground and a wall of a building.

### 2. Description of Related Art

In general, when arranging building materials such as tiles on the wall of a building, the area of an arrangement area is calculated, the area is divided by the area of the building material and then is multiplied by a loss rate, and the required number is required by displaying a grid and counting. In recent years, a method and a system have been proposed, in which an arrangement condition data such as building material size and arrangement area drawing data are input to the computer, and the computer displays the state when the building materials are arranged in the arrangement area, and automatically calculates the required number of building materials (see JP Patent Publication No. 2002-342386, JP Patent Publication No. 2004-3186651, JP Patent Publication No. 2005-242923, JP Patent Publication No. 2014-152528, JP Patent Publication No. 2018-178489, and JP Patent No. 3965165).

By the way, in an actual building, there may be an area where the building materials are not arranged, such as windows, pillars, and doors, in the arrangement area. In this case, when the required number of building materials is obtained by the method or system as described above, the required number of building materials cannot be accurately obtained because the quantity in the area where the building materials are not arranged is calculated as the required number of building materials.

### SUMMARY OF THE INVENTION

Thus, the present invention is made in view of the subject mentioned above, and it aims at providing a building material estimation system and the like which can obtain the required number of building materials correctly.

The present invention is a building material estimation system, comprising:
a base diagram acquiring unit for acquiring a base diagram including a construction area where building materials are arranged;
an arrangement diagram generating unit for generating a building material arrangement diagram which is formed in such a way that a building material group in which a plurality of the building materials is arranged covers the construction area;
a display controlling unit for controlling a display device to display the building material arrangement diagram and the construction area of the base diagram in an overlapping manner;
an editing unit for performing an editing process for deleting a part of the building material group in the building material arrangement diagram in a unit of a building material according to an assignment from the outside;
a counting unit for obtaining the number of the building materials constituting the building material group in the building material arrangement diagram; and
an output unit for outputting the number of the building materials to an outside.

According to the above configuration, since the number of building materials can be finely adjusted by deleting a part of the building material group in a unit of a building material according to the assignment from the outside, the required number of building materials can be obtained with high accuracy.

The editing unit of the building material estimation system of the present invention performs an editing process for adding the building materials to a position assigned from the outside in the building material arrangement diagram.

According to the above configuration, since the number of building materials can be finely adjusted by adding building materials to the position assigned from the outside in the building material arrangement diagram, the required number of building materials can be obtained with high accuracy.

The editing unit of the building material estimation system of the present invention performs an editing process for relatively moving the building material arrangement diagram and the construction area of the base diagram displayed on the display device by an operation from the outside.

According to the above configuration, the editing work can be easily performed by relatively moving the building material arrangement diagram and the construction area of the base diagram displayed on the display device by the operation from the outside.

The building material estimation system according to the present invention comprises an avoidance assigning unit for assigning from the outside an arrangement avoidance area where the building materials are not arranged in the construction area in the base diagram, and the arrangement diagram generating unit generates a building material arrangement diagram which is formed in such a way that the building material group covers the construction area except for the arrangement avoidance area.

According to the above configuration, the building material arrangement diagram is formed in such a way that the building material group is generated to cover the construction area except for the arrangement avoidance area, so that the editing work can be easily performed.

In the building material estimation system of the present invention, the base diagram acquiring unit acquires the base diagram having a plurality of the construction areas, the arrangement diagram generating unit generates the building material arrangement diagram for the construction area, and the editing unit performs the editing process for the building material arrangement diagram.

According to the above configuration, the editing work can be quickly performed by performing the editing process for the building material arrangement diagram of a plurality of construction areas.

The building material estimation system of the present invention comprises:
a base diagram acquiring unit for acquiring a base diagram including a ground construction area and a wall construction area where building materials are arranged;
an arrangement diagram generating unit for generating a ground building material arrangement diagram, which is formed in such a way that a building material group in which a plurality of the building materials are arranged covers the ground construction area, and a wall construction array, which is formed in such a way that the building material group covers the wall construction area;
a display controlling unit for controlling a display device in such a way that two reference points and one direction point on an area line of the ground construction area can be assigned from the outside and the wall construction area and the wall building material arrangement diagram in an area on the area line connecting the reference points and including the direction points are displayed as an unfolding diagram;
an editing unit for performing an editing process for deleting a part of the building material group in the ground building material arrangement diagram and the wall building material arrangement diagram in a unit of a building material according to an assignment from the outside;
a counting unit for obtaining the number of the building materials constituting the building material group in the ground building material arrangement diagram and the wall building material arrangement diagram respectively; and
an output unit for outputting the number of the building materials to an outside.

According to the above configuration, it is possible to confirm the unfolding diagram of the wall by a simple operation of simply assigning two reference points and one direction point in the ground building material arrangement diagram.

The building material estimation system of the present invention comprises:
a database unit for storing a design diagram file including design diagram data of a building, a building material specification file including size data and shape data of the building material, and a pattern file including arrangement pattern data of the building material;
a base diagram acquiring unit for acquiring a base diagram including a construction area in which building materials are arranged based on the design diagram data of the database unit;
a building material assigning unit for assigning the size data and the shape data in the building material specification file and the arrangement pattern in the pattern file from the outside;
an arrangement diagram generating unit for generating a building material arrangement diagram which is formed in such a way that a building material group in which the building materials are arranged covers the construction area, based on the size data, the shape data, and the arrangement pattern data assigned by the building material assigning unit.
a display controlling unit for controlling a display device to display the building material arrangement diagram and the construction area of the base diagram in an overlapping manner;
an editing unit for performing an editing process for deleting a part of the building material group in the building material arrangement diagram in a unit of a building material according to an assignment from the outside and for adding the building material to a position assigned from the outside in the building material arrangement diagram;
a counting unit for obtaining the number of the building materials constituting the building material group in the building material arrangement diagram; and
an output unit for outputting the number of the building materials to an outside.

According to the above configuration, since the number of building materials can be finely adjusted by deleting a part of the building material group in a unit of a building material according to the assignment from the outside, the required number of building materials can be obtained with high accuracy.

A building material estimation method for determining the number of building materials to be arranged in a construction area of a building, comprising:
a step of base diagram acquiring for acquiring a base diagram of a construction area where building materials are arranged;
a step of arrangement diagram generating for generating a building material arrangement diagram which is formed in such a way that a building material group in which a plurality of the building materials is arranged covers the construction area;
a step of display controlling for controlling a display device to display the building material arrangement diagram and the construction area of the base diagram in an overlapping manner;
a step of editing for performing an editing process for deleting a part of the building material group in the building material arrangement diagram in a unit of a building material according to an assignment from the outside;
a step of counting for obtaining the number of the building materials constituting the building material group in the building material arrangement diagram; and
a step of output for outputting the number of the building materials to an outside.

According to the above configuration, since the number of building materials can be finely adjusted by deleting a part of the building material group in a unit of a building material according to the assignment from the outside, the required number of building materials can be obtained with high accuracy.

A management server of a building material estimation system for determining the number of building materials to be arranged in a construction area of a building, comprising:
a base storage device for storing a base diagram (all or part of a ground, a wall, or a ceiling) including a construction area in which building materials are arranged; a communication device for accessing an external terminal; and
wherein the controller performs:
a base diagram acquiring process for acquiring the base diagram from the base storage device;
an arrangement diagram generating process for generating a building material arrangement diagram which is formed in such a way that a building material group in which a plurality of the building materials is arranged covers the construction area;
a display controlling process for controlling the external terminal to display the building material arrangement diagram and the construction area of the base diagram in an overlapping manner;
an editing process for performing an editing process for deleting a part of the building material group in the building material arrangement diagram in a unit of a building material according to an assignment from the external terminal;
a counting process for obtaining the number of the building materials constituting the building material group in the building material arrangement diagram; and
an output process for outputting the number of the building materials to the external terminal.

According to the above configuration, since the number of building materials can be finely adjusted by deleting a part of the building material group in a unit of a building material according to the assignment from the outside, the required number of building materials can be obtained with high accuracy.

A computer-readable non-transitory medium for storing a building material estimation program of the present invention, wherein a computer functions as:
a base diagram acquiring unit for acquiring a base diagram including a construction area where building materials are arranged;
an arrangement diagram generating unit for generating a building material arrangement diagram which is formed in such a way that a building material group in which a plurality of the building materials is arranged covers the construction area;
a display controlling unit for controlling a display device to display the building material arrangement diagram and the construction area of the base diagram in an overlapping manner;
an editing unit for performing an editing process for deleting a part of the building material group in the building material arrangement diagram in a unit of a building material according to an assignment from the outside;
a counting unit for obtaining the number of the building materials constituting the building material group in the building material arrangement diagram; and
an output unit for outputting the number of the building materials to an outside.

According to the above configuration, since the number of building materials can be finely adjusted by deleting a part of the building material group in a unit of a building material according to the assignment from the outside, the required number of building materials can be obtained with high accuracy.

The present invention may be a building material estimation system that calculates building materials in consideration of openings. Specifically, it is as follows.

The building material estimation system of the present invention comprises:
a base diagram acquiring unit for acquiring a base diagram and storing it in a memory;
a construction area setting unit for setting a construction area in which building materials are arranged in the base diagram stored in the memory by operating an external device;
an avoidance assigning unit for assigning an arrangement avoidance area in which the building materials are not arranged in the construction area by operating an external device;
an arrangement diagram generating unit for unfolding a building material group in which the building materials are arranged in the memory, and generating a building material arrangement diagram which is formed in such a way that the building material group covers the construction area;
a display controlling unit for controlling a display device to display the building material arrangement diagram, the construction area, and the arrangement avoidance area in an overlapping manner;
a counting unit for obtaining the number of the building materials constituting the building material group in the building material arrangement diagram by determining the number of constructions of the building materials which at least overlap partially in the construction area and the number of avoidances of the building materials included completely in the arrangement avoidance area according to the building material group, the construction area, and the arrangement avoidance area unfolded in the memory and subtracting the number of avoidances from the number of constructions; and
an output unit for outputting the number of the building materials to an outside.

According to the above configuration, the required number of building materials can be obtained correctly by subtracting the number of avoidances from the number of constructions.

The building material estimation system of the present invention comprises an editing unit for performing an editing process for relatively moving at least a part of the building material group in the building material arrangement diagram and the construction area displayed on the display device by operating the external device.

According to the above configuration, the editing process of relative movement can be easily performed.

The building material estimation system of the present invention comprises an editing unit for performing an editing process for changing, by operating the external device, with respect to the construction area, an angle of at least a part of the building material group in the building material arrangement diagram displayed on the display device.

According to the above configuration, the editing process of angle change can be easily performed.

The building material estimation system of the present invention comprises an editing unit for performing an editing process for deleting at least a part of the building material group in the building material arrangement diagram displayed on the display device in a unit of a building material according to an assignment from the external device.

According to the above configuration, the editing process of deleting in a unit of a building material can be easily performed.

The building material estimation system of the present invention, wherein the arrangement diagram generating unit generates a building material arrangement diagram in which the building materials are arranged in a herringbone arrangement.

According to the above configuration, the number of building materials arranged in a herringbone arrangement can be obtained.

The present invention is a building material estimation method for determining the number of building materials to be arranged in a construction area of a building, comprising:
a step of base diagram acquiring for acquiring a base diagram and storing it in a memory;
a step of construction area setting for setting a construction area in which building materials are arranged in the base diagram stored in the memory by operating an external device;
a step of avoidance assigning for assigning an arrangement avoidance area in which the building materials are not arranged in the construction area by operating an external device;
a step of arrangement diagram generating for unfolding a building material group in which the building materials are arranged in the memory, and generating a building material arrangement diagram which is formed in such a way that the building material group covers the construction area;
a step of display controlling for controlling a display device to display the building material arrangement diagram, the construction area, and the arrangement avoidance area in an overlapping manner;
a step of counting for obtaining the number of the building materials constituting the building material group in the building material arrangement diagram by determining the number of constructions of the building materials which at least overlap partially in the construction area and the number of avoidances of the building materials included completely in the arrangement avoidance area according to the building material group, the construction area, and the arrangement avoidance area unfolded in the memory and subtracting the number of avoidances from the number of constructions; and
a step of output for outputting the number of the building materials to an outside.

According to the above configuration, the required number of building materials can be obtained correctly by subtracting the number of avoidances from the number of constructions.

The present invention is a management server of a building material estimation system for obtaining the number of building materials to be arranged in a construction area of a building, comprising: a memory for storing various data including data related to the number of the building materials; and a controller,
wherein the controller performs:
a base diagram acquiring process for acquiring the base diagram and storing it in a memory;
a construction area setting process for setting a construction area in which building materials are arranged in the base diagram stored in the memory by operating an external device;
an avoidance assigning process for assigning an arrangement avoidance area in which the building materials are not arranged in the construction area by operating an external device;
an arrangement diagram generating process for unfolding a building material group in which the building materials are arranged in the memory, and generating a building material arrangement diagram which is formed in such a way that the building material group covers the construction area;
a display controlling process for controlling a display device to display the building material arrangement diagram, the construction area, and the arrangement avoidance area in an overlapping manner;
a counting process for obtaining the number of the building materials constituting the building material group in the building material arrangement diagram by determining the number of constructions of the building materials which at least overlap partially in the construction area and the number of avoidances of the building materials included completely in the arrangement avoidance area according to the building material group, the construction area, and the arrangement avoidance area unfolded in the memory and subtracting the number of avoidances from the number of constructions; and
an output process for outputting the number of the building materials to an outside.

According to the above configuration, the required number of building materials can be obtained correctly by subtracting the number of avoidances from the number of constructions.

The present invention may be a building material estimation device for herringbone.

Specifically, it is as follows.

The present invention is a building material estimation device for obtaining the number of building materials to be arranged in a herringbone arrangement in a construction area of a building, comprising a memory and a controller, and wherein the memory stores various data including data related to the number of the building materials,
wherein the controller performs:
a base diagram acquiring process for acquiring a base diagram and storing it in a memory;
a construction area setting process for setting a construction area in which building materials are arranged in the base diagram stored in the memory by operating an external device;
an arrangement diagram generating process for unfolding a building material group in which the building materials are arranged in the herringbone arrangement in the memory, and generating a building material arrangement diagram which is formed in such a way that the building material group covers the construction area;
a display controlling process for controlling a display device to display the building material arrangement diagram and the construction area in an overlapping manner;
a counting process for obtaining the number of the building materials constituting the building material group in the building material arrangement diagram, according to the building material group unfolded in the memory and the construction area; and
an output process for outputting the number of the building materials to an outside,
wherein, in the counting process,
a regular quadrilateral determination area where the construction area can be completely accommodated is determined,
a position of a center point of the building material arranged in a herringbone is obtained in the determination area as an installation location candidate,
the building materials are unfolded on the memory for all the installation location candidates in the determination area, and the number of the building materials overlapping in the construction area is obtained.

Conventionally, since there is no configuration in which building materials are arranged in a herringbone arrangement, the number of building materials in a herringbone arrangement cannot be obtained; however, according to the above configuration, the number of building materials in a herringbone arrangement can be obtained.

The controller of the present invention performs an avoidance assigning process for assigning an arrangement avoidance area in which the building materials are not arranged in the construction area by operating an external device,
in the counting process, the number of constructions of the building materials which at least overlap partially in the construction area and the number of avoidances of the building materials included completely in the arrangement avoidance area are determined according to the building material group, the construction area, and the arrangement avoidance area unfolded in the memory, and the number of avoidances is subtracted from the number of constructions in order to obtain the number of the building materials.

According to the above configuration, the number of building materials can be obtained correctly by subtracting the number of avoidances from the number of constructions.

The present invention may be a building material estimation device that generates a construction area excluding an avoidance component such as a pillar. Specifically, it is as follows.

The present invention is a building material estimation device for obtaining the number of building materials to be arranged in a construction area of a building, comprising a memory and a controller, and wherein the memory stores various data including data related to the number of the building materials,
wherein the controller performs:
a base diagram acquiring process for acquiring a base diagram and storing it in a memory;
a construction area setting process for setting a construction area in which building materials are arranged in the base diagram stored in the memory by operating an external device;
an avoidance assigning process for assigning an arrangement avoidance area in which building materials are not arranged in the base diagram stored in the memory by operating an external device;
a construction area changing process in which a first layer that stores the construction area as a true value (1) and stores others except for the construction area as a false value (0) and second layer that stores the arrangement avoidance area as a false value (0) and stores others except for the arrangement avoidance area as a true value (1) are set in the memory, and an area where the construction area and the arrangement avoidance area overlap is obtained as the arrangement avoidance area by performing an AND operation to the first layer and the second layer;
an arrangement diagram generating process for unfolding a building material group in which the building materials are arranged in the memory, and generating a building material arrangement diagram which is formed in such a way that the building material group covers the construction area;
a display controlling process for controlling a display device to display the building material arrangement diagram, the construction area, and the arrangement avoidance area in an overlapping manner;
a counting process for obtaining the number of the building materials constituting the building material group in the building material arrangement diagram, according to the building material group unfolded in the memory and the construction area; and
an output process for outputting the number of the building materials to an outside.

In an actual building, there may be an area where the building materials are not arranged, such as windows, pillars, and doors. In this case, when an arrangement area is set by a conventional method or system, if a pillar or the like arranged at the corner of a room or the center of a wall exists on a boundary line of the arrangement area, a process for avoiding the pillar is required, and thus, there is a problem that it may take time to set the arrangement area. However, according to the above configuration, by performing an AND operation to the first layer that stores the construction area as the true value (1) and the area other than the construction area as the false value (0) and the second layer that stores the arrangement avoidance area as the false value (0) and the area other than the arrangement avoidance area as true value (1), an area where the construction area and the arrangement avoidance area overlap is set as the arrangement avoidance area, and thus, the construction area can be easily set.

According to the present invention, the required number of building materials can be obtained correctly by subtracting the number of avoidances from the number of constructions.

### BRIEF DESCRIPTION OF THE DRAWINGS

FIG. 1A is a block diagram of a building material estimation system.

FIG. 1B is an illustrative diagram of a building material arrangement diagram.

FIG. 1C is an illustrative diagram of a building material arrangement diagram.

FIG. 1D is an illustrative diagram of a building material arrangement diagram.

FIG. 1E is an illustrative diagram of a building material arrangement diagram.

FIG. 1F is an illustrative diagram of a building material arrangement diagram.

FIG. 1G is an illustrative diagram of a building material arrangement diagram.

FIG. 2 is a flow chart of a building material estimation program.

FIG. 3 is a block diagram of a building material estimation system.

FIG. 4A is an illustrative diagram showing an editing process of a building material arrangement diagram.

FIG. 4B is an illustrative diagram showing an editing process of a building material arrangement diagram.

FIG. 5A is an illustrative diagram showing an editing process of a building material arrangement diagram.

FIG. 5B is an illustrative diagram showing an editing process of a building material arrangement diagram.

FIG. 5C is an illustrative diagram showing an editing process of a building material arrangement diagram.

FIG. 6 is an illustrative diagram showing an editing process of a building material arrangement diagram.

FIG. 7 is an illustrative diagram showing an editing process of a building material arrangement diagram.

FIG. 8 is an illustrative diagram showing an editing process of a building material arrangement diagram.

FIG. 9 is an illustrative diagram showing an editing process of a building material arrangement diagram.

FIG. 10 is an illustrative diagram showing an editing process of a building material arrangement diagram.

FIG. 11 is an illustrative diagram of image processing.

FIG. 12 is an illustrative diagram showing a process of generating an unfolded diagram.

FIG. 13A is an illustrative diagram showing a process of generating an unfolded diagram.

FIG. 13B is an illustrative diagram showing a process of generating an unfolded diagram.

FIG. 13C is an illustrative diagram showing a process of generating an unfolded diagram.

FIG. 13D is an illustrative diagram showing a process of generating an unfolded diagram.

FIG. 13E is an illustrative diagram showing a process of generating an unfolded diagram.

FIG. 14 is a flow chart of a herringbone counting process.

FIG. 15 is a flow chart of a necessity determining process.

FIG. 16A is an illustrative diagram of the herringbone counting process.

FIG. 16B is an illustrative diagram of the herringbone counting process.

FIG. 17A is an illustrative diagram a drawing unit.

FIG. 17B is an illustrative diagram of an enlarged display screen.

FIG. 18 is an illustrative diagram showing a tab management method of a building material estimation system.

FIG. 19 is an illustrative diagram of project information processing.

FIG. 20 is an illustrative diagram of a floor generating process.

FIG. 21 is an illustrative diagram of a floor generating process.

FIG. 22 is an illustrative diagram of a floor generating process.

FIG. 23 is an illustrative diagram of a ground generating process.

FIG. 24 is an illustrative diagram of a ground generating process.

FIG. 25 is an illustrative diagram of a ground generating process.

FIG. 26 is an illustrative diagram of a ground generating process.

FIG. 27 is an illustrative diagram of a ground generating process.

FIG. 28 is an illustrative diagram of a ground generating process.

FIG. 29 is an illustrative diagram of a ground generating process.

FIG. 30 is an illustrative diagram of a ground generating process.

FIG. 31 is an illustrative diagram of a ground generating process.

FIG. 32 is an illustrative diagram of a ground generating process.

FIG. 33 is an illustrative diagram of a ground generating process.

FIG. 34 is an illustrative diagram of a ground generating process.

FIG. 35 is an illustrative diagram of a ground generating process.

FIG. 36 is an illustrative diagram of a partition generating process.

FIG. 37 is an illustrative diagram of a partition editing process.

FIG. 38 is an illustrative diagram of a partition editing process.

FIG. 39 is an illustrative diagram of a partition unfolding process.

FIG. 40 is an illustrative diagram of a wall generating process.

FIG. 41 is an illustrative diagram of a wall unfolding process.

FIG. 42 is an illustrative diagram of ceiling processing.

FIG. 43 is an illustrative diagram of ceiling processing.

### DESCRIPTION OF THE PREFERRED EMBODIMENTS

### (Outline of a Building Material Estimation System)

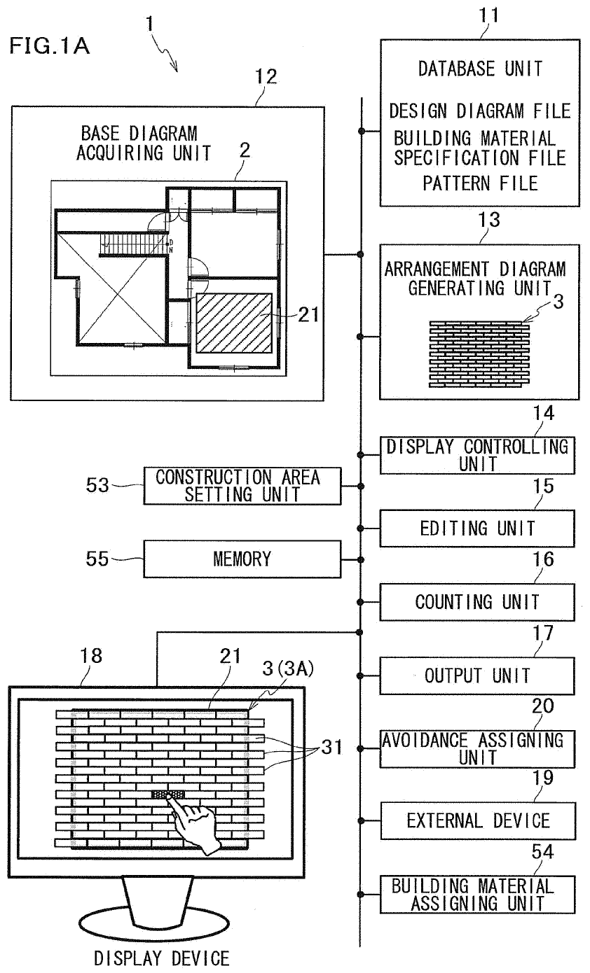

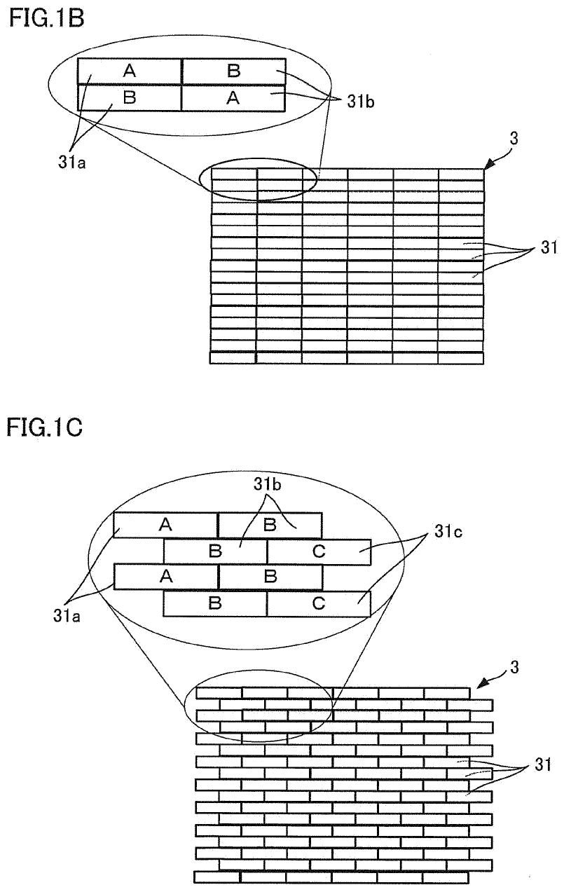

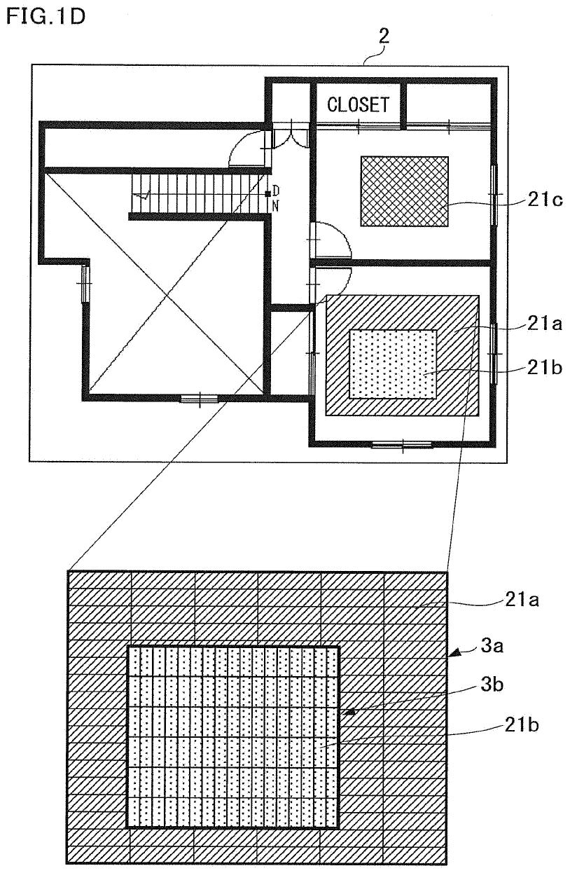

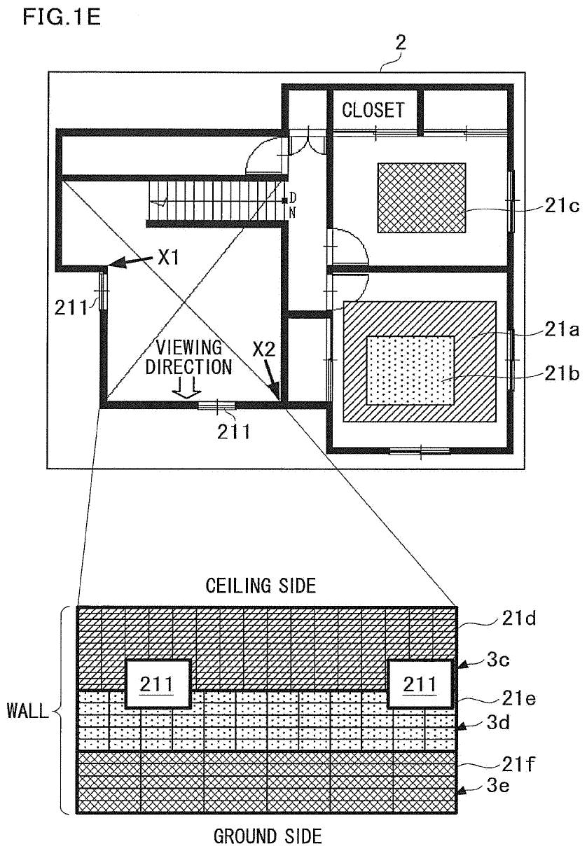

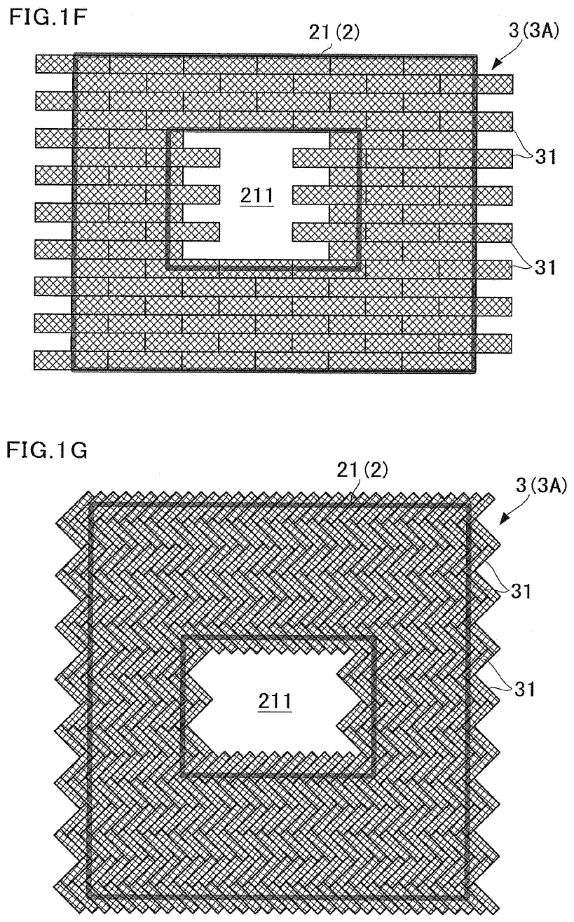

As shown in FIG. 1A, the building material estimation system 1 of the present embodiment displays an image in which a building material group 3 composed of a plurality of building materials 31 is allocated to a construction area 21 such as a ceiling, a wall, or a ground in a predetermined arrangement pattern on a device 18, and performs adding, deleting, changing, moving and the like to the building material 31 for a part or all of the building material group 3 by one unit.

More specifically, the building material estimation system 1 comprises a database unit 11 for storing a design diagram file including design diagram data of a building such as a house or an edifice, a building material specification file including size data and shape data of the building material 31, and a pattern file including arrangement pattern data of the building material 31.

Here, “design diagram” is a diagram whose main purpose is to convey the design of the entire building, such as the form and floor plan, and is an arrangement diagram, a plan view, a roof plan view, an elevation view, a sectional view, a development view and the like, for example. In addition to CAD data, the design diagram may also be a diagram such as a leaflet used for home sales, etc. converted into electronic data by a scanner or a camera.

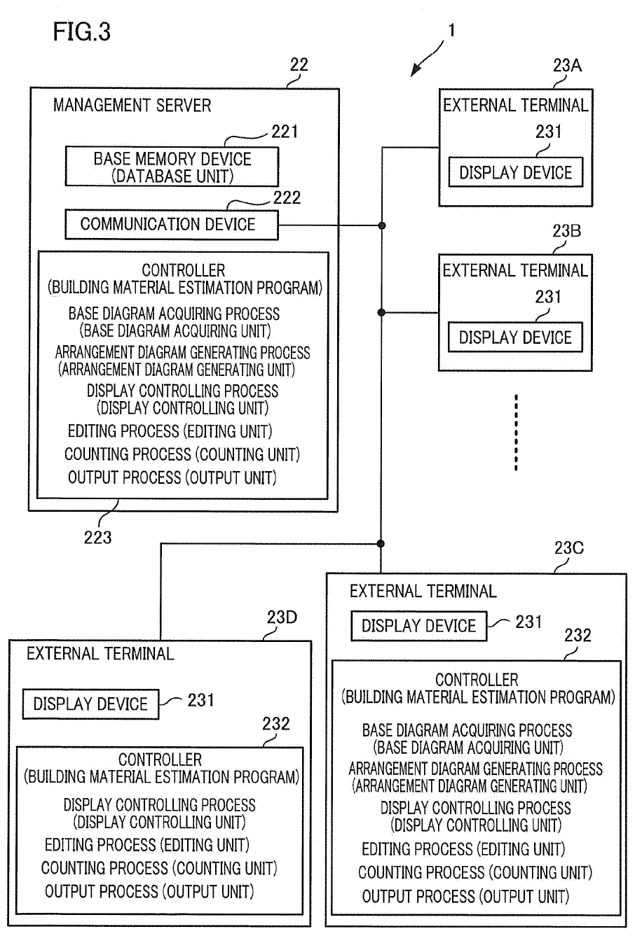

The “building material specification file” may include various data such as material, product name, product number, price, and sales address in addition to the size data and shape data of the building material 31. As the building material 31, a rectangular panel such as a rectangle is exemplified, but other shapes such as a circle and a polygon may be used, or a material having a property of elastic deformation and plastic deformation is possible as long as the shape can be maintained. Furthermore, the building material specification is preferably automatically updated at an appropriate timing from a website such as a building material manufacturer or a building material sales company via the Internet. In addition, examples of the arrangement pattern data include a lattice arrangement, a width shift arrangement, and a herringbone arrangement. The arrangement pattern data is not limited to the three types of examples of the lattice arrangement, the width shift arrangement, and the herringbone arrangement, and it is preferable that an arrangement in which various building materials are regularly combined can be pre-registered. For example, as shown in FIG. 1B, a configuration in which an arrangement group where A building materials and B building materials are alternately arranged in a horizontal direction are stacked in a vertical direction may be pre-registered, or as shown in FIG. 3C, a configuration in which a first arrangement group where A building materials and B building materials are alternately arranged in the horizontal direction and a second arrangement group where B building materials and C building materials are alternately arranged in the horizontal direction are stacked with the width shifted alternately in the vertical direction may be pre-registered.

Furthermore, the building material estimation system 1 comprises a base diagram acquiring unit 12 that acquires a base diagram 2 including the construction area 21 in which the building materials 31 are arranged and stores the base diagram 2 in a memory 55. Moreover, when the building material group 3 is obtained in a state where the base diagram 2 does not include the construction area 21, the entire design diagram in the base diagram 2 becomes the construction area 21. The base diagram acquiring unit 12 has an accessing function for accessing the database unit 11 to acquire at least design diagram data and a base diagram generating function for generating the base diagram 2 based on the design diagram data. The base diagram generating function is a function that sets the construction area 21 where an operator is enabled to construct in the base diagram 2 representing all or part of the ground, wall, and ceiling surface, etc. based on design diagram data input from devices such as a scanner and a camera in addition to the design diagram data acquired from the database unit 11.

The base diagram acquiring unit 12 has a construction area setting function for setting a plurality of construction areas 21 by operating an external device 19 in the base diagram 2 stored in the memory 55. In addition, the construction area setting function may be other function of a construction area setting unit 53 than the function of the base diagram acquiring unit 12. The setting mode of the construction area 21 may be distributed so that the plurality of construction areas 21 do not overlap each other, or a part or all of the other construction areas 21 are overlapped with respect to a specific construction area 21. For example, in FIG. 1D, three construction areas of first to third construction areas 21a to 21c are set on the ground of the base diagram 2, all of the second construction area 21b is arranged in an overlapping manner inside the first construction area 21a, and the third construction area 21c is arranged in a distributed manner with respect to the first construction area 21a and the second construction area 21b. In addition, FIG. 1E shows a state where three construction areas of fourth to sixth construction areas 21d to 21f are independently arranged in an up and down direction (a vertical direction) on the wall of the base diagram 2. Furthermore, FIG. 1E shows a wall from a point X1 to a point X2 in an arrow direction (viewing direction) visually observed from the inside of the room towards the outside as an unfolded diagram, and shows a state where openings such as windows are arranged at two locations in the wall as an arrangement avoidance area 211. A method for displaying the wall of a plan view as an unfolded diagram will be described later.

Furthermore, the building material estimation system 1 comprises an arrangement diagram generating unit 13 that unfolds the building material group 3 in which a plurality of building materials 31 are arranged in the memory 55 and generates a building material arrangement diagram 3A which is formed in such a way that the building material group 3 covers the construction area 21, a display controlling unit 14 that controls a display device 18 so as to display the building material arrangement diagram 3A and the construction area 21 of the base diagram 2 in an overlapping manner, an editing unit 15 that performs an editing process for deleting a part of the building material group 3 in the building material arrangement diagram 3A in a unit of a building material according to an instruction from the external device 19, a counting unit 16 that obtains the number of building materials 31 constituting the building material group 3 in the building material arrangement diagram 3A, and an output unit 17 that outputs the number of the building materials 31 to the outside. Moreover, the output unit 17 may be the display device 18 that displays the number of building materials 31 or may be another information processing device. In addition, when outputting in a data format to the outside, the output unit 17 preferably outputs with an extension set by an operator. For example, when the extension of Excel (registered trademark) is set, the number list data of the building materials 31 is output with the extension of Excel (registered trademark).

Thereby, since the building material estimation system 1 can finely adjust the number of the building materials 31 by deleting a part of the building material group 3 in a unit of a building material according to an assignment from the outside, the required number of the building materials 31 can be obtained with high accuracy. Here, “assignment from the outside” refers to assigning by the operator operating the external device 19 such as a mouse or a touch panel. Further, the editing unit 15 preferably performs various editing processes such as an editing process of adding in a unit of a building material, a movement and a change in a unit of a building material, in addition to the editing process of deleting in a unit of a building material. Details of the editing process will be described later.

In addition, preferably, in the building material estimation system 1, the base diagram acquiring unit 12 acquires the base diagram 2 having a plurality of construction areas 21, the arrangement diagram generating unit 13 generates the building material arrangement diagram 3A for the construction area 21, and the editing unit 15 performs the editing process for the building material arrangement diagram 3A. In this case, the editing work can be quickly performed by performing the editing process for the building material arrangement diagram 3A of a plurality of construction areas.

Thereby, for example, as shown in FIG. 1D, a building material group 3a in which horizontal building materials are arranged in the horizontal direction is arranged in the first construction area 21a, and a building material group 3b in which vertical building materials are arranged in the vertical direction is arranged in the second construction area 21b, and with this configuration, the editing work can be performed for each of the building material groups 3a and 3b. Further, for example, as shown in FIG. 1E, different building materials can be arranged in each of the three construction areas of fourth to sixth construction areas 21d to 21f to perform editing work.

In addition, it is preferable to have a function capable of collectively forming the building material arrangement diagram 3A of the building material group 3a in these construction areas 21, after an operation of assigning any one or more construction areas 21 and selecting a building material 31 used in the assigned construction area 21 is performed for all of the construction areas 21, when there are a plurality of construction areas 21. Here, “selecting a building material 31” refers to selecting a type, a size, a vertical arrangement, a horizontal arrangement, an inclined arrangement, and the like of the building material 31.

In this case, for example, as shown in FIG. 1E, after different building materials are allocated to the three constructions of fourth to sixth construction areas 21d to 21f, the building material arrangement diagram of the building material groups 3c, 3d, and 3e in the fourth to sixth construction areas 21d to 21f can be collectively formed by a predetermined switch operation. As a result, the selection of the building materials 31 used in all the fourth to sixth construction areas 21d to 21f can be completed in advance, and it can thereby reduce the selection mistake of the building materials 31 in the fourth to sixth construction areas 21d to 21f.

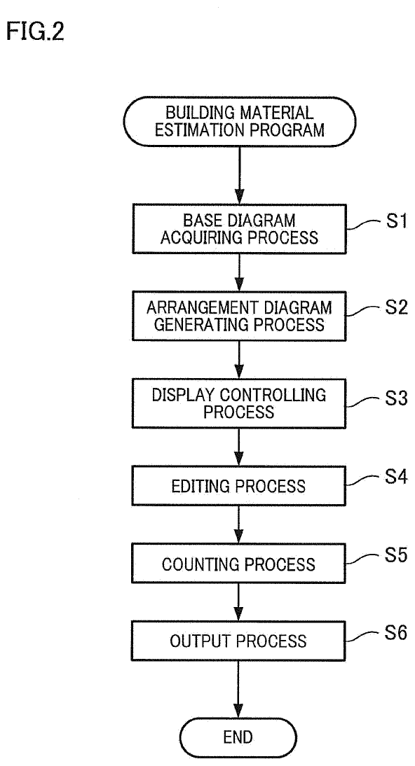

For the building material estimation system 1, some functions of each processing unit thereof may be realized by a building material estimation program installed in the information processing device. For example, as shown in FIG. 2, the building material estimation program is configured to enable a computer of the information processing device to function as the base diagram acquiring unit 12, the arrangement diagram generating unit 13, the display controlling unit 14, the editing unit 15, the counting unit 16, and the output unit 17. That is, the building material estimation program causes the computer to perform a base diagram acquiring process (S1) for acquiring the base diagram 2 including the construction area 21 in which the building materials 31 are arranged, an arrangement diagram generating process (S2) for generating the building material arrangement diagram which is formed in such a way that the building material group 3 in which a plurality of building materials 31 are arranged covers the construction area 21, a display controlling process (S3) for controlling the display device 18 so as to overlap and display the building material arrangement diagram 3A and the construction area 21 of the base diagram 2, an editing process (S4) for deleting a part of the building material group 3 in the building material arrangement diagram 3A in a unit of a building material according to the assignment from the outside, a counting process (S5) for obtaining the number of building materials 31 constituting the building material group 3 in the building material arrangement diagram 3A, and an output process for outputting the number of building materials 31 to the outside. In addition, the editing process (S4) includes adding, deleting, changing, moving, and the like of the building material 31 in one unit for a part or all of the building material group 3. In addition, the building material estimation program may be distributed in a state of being recorded on a recording medium such as a CDROM or a USB memory, or distributed via a two-way communication network or communication line such as the Internet or a one-way communication network or communication line such as a television broadcast.

### (Number of Building Materials Correcting Function for Arrangement Avoidance Area)

As shown in FIG. IF and FIG. 1G, in the arrangement diagram generating process (S2), when there is the arrangement avoidance area 211 where the building material 31 is not arranged, such as an opening, in the construction area 21, the building material arrangement diagram 3A of the building material group 3 excluding this arrangement avoidance area 211 is formed. Here, FIG. 1F shows a state in which the building material group 3 having the width shift arrangement is displayed in the construction area 21 having the arrangement avoidance area 211 inside, and FIG. 1G shows a state in which the building material group 3 having the herringbone arrangement is displayed in the construction area 21 having the arrangement avoidance area 211 inside.

In the counting process (S5) in this case, the number of building materials 31 arranged in the arrangement avoidance area 211 is subtracted from the total number of building material groups 3 (building material arrangement diagram 3A) at least partially overlapping in the construction area 21, and the total number after subtraction is displayed on the screen. In addition, the total number before subtraction and the subtraction number (the number of building materials 31 arranged in the arrangement avoidance area 211) may also be displayed on the screen together with the total number after subtraction.

The building material estimation system 1, the building material estimation method, and the management server of the building material estimation system having a building material correcting function are configured as follows.

The building material estimation system 1 comprises the base diagram acquiring unit 12 that acquires the base diagram 2 and stores the base diagram 2 in the memory 55, the construction area setting unit 53 that sets the construction area 21 in which the building materials 31 are arranged in the base diagram 2 stored in the memory 55 by operation of the external device 19, the avoidance assigning unit 20 that assigns the arrangement avoidance area 211 in which the building material 31 is not arranged in the construction area 21 by the operation of the external device 19, the arrangement diagram generating unit 13 that unfolds the building material group 3 in which the building materials 31 are arranged in the memory 55 and generates the building material arrangement diagram which is formed in such a way that the building material group 3 covers the construction area 21, the display controlling unit 14 that controls the display device 18 to display the building material arrangement diagram, the construction area 21, and the arrangement avoidance area 211 in an overlapping manner, the counting unit 16 that obtains the number of the building materials 31 constituting the building material group 3 in the building material arrangement diagram by determining the number of constructions of the building materials 31 which at least overlap partially in the construction area 21 and the number of avoidances of the building materials 31 included completely in the arrangement avoidance area 211 according to the building material group 3, the construction area 21, and the arrangement avoidance area 211 unfolded in the memory 55 and subtracting the number of avoidances from the number of constructions, and the output unit 17 that outputs the number of building materials 31 to the outside.

The building material estimation system comprises a step of base diagram acquiring that acquires the base diagram 2 and stores the base diagram in the memory, a step of construction area setting that sets the construction area 21 in which the building materials 31 are arranged in the base diagram 2 stored in the memory 55 by operation of the external device 19, a step of avoidance assigning that assigns the arrangement avoidance area 211 in which the building material 31 is not arranged in the construction area 21 by the operation of the external device 19, a step of arrangement diagram generating that unfolds the building material group 3 in which the building materials 31 are arranged in the memory 55 and generates the building material arrangement diagram which is formed in such a way that the building material group 3 covers the construction area 21, a step of display controlling that controls the display device 18 to display the building material arrangement diagram, the construction area 21, and the arrangement avoidance area 211 in an overlapping manner, a step of counting that obtains the number of the building materials 31 constituting the building material group 3 in the building material arrangement diagram by determining the number of constructions of the building materials 31 which at least overlap partially in the construction area 21 and the number of avoidances of the building materials 31 included completely in the arrangement avoidance area 211 according to the building material group 3, the construction area 21, and the arrangement avoidance area 211 unfolded in the memory 55 and subtracting the number of avoidances from the number of constructions, and a step of output that outputs the number of building materials 31 to the outside.

The management server of the building material estimation system comprises the memory 55 that stores various data including data related to the number of the building materials 31, and a controller that performs: a base diagram acquiring process (the base diagram acquiring unit 12) that acquires the base diagram 2 and stores the base diagram 2 in the memory 55, a construction area setting process (the construction area setting unit 53) that sets the construction area 21 in which the building materials 31 are arranged in the base diagram 2 stored in the memory 55 by operating the external device 19, an avoidance assigning process (the avoidance assigning unit 20) that assigns the arrangement avoidance area 211 in which the building material 31 is not arranged in the construction area 21 by operating the external device 19, an arrangement diagram generating process (the arrangement diagram generating unit 13) that unfolds the building material group 3 in which the building materials 31 are arranged in the memory 55 and generates the building material arrangement diagram which is formed in such a way that the building material group 3 covers the construction area 21, a display controlling process (the display controlling unit 14) that controls the display device 18 to display the building material arrangement diagram, the construction area 21, and the arrangement avoidance area 211 in an overlapping manner, a counting process (the counting unit 16) that obtains the number of the building materials 31 constituting the building material group 3 in the building material arrangement diagram by determining the number of constructions of the building materials 31 which at least overlap partially in the construction area 21 and the number of avoidances of the building materials 31 included completely in the arrangement avoidance area 211 according to the building material group 3, the construction area 21, and the arrangement avoidance area 211 unfolded in the memory 55 and subtracting the number of avoidances from the number of constructions, and an output process (the output unit 17) that outputs the number of building materials 31 to the outside.

According to the above configuration of the building material estimation system 1, the building material estimation method, and the management server, the required number of building materials 31 can be obtained correctly by subtracting the number of avoidances from the number of constructions.

In addition, the building material estimation system 1 realizes a building material estimation method for obtaining the number of building materials arranged in the construction area 21 (all or a part of a ground, a wall, or a ceiling surface) of a building (house, edifice, etc.). More specifically, the building material estimation method comprises a step of base diagram acquiring for acquiring the base diagram 2 including the construction area 21 in which the building materials 31 are arranged, a step of arrangement diagram generating for generating the building material arrangement diagram 3A which is formed in such a way that the building material group 3 in which a plurality of building materials 31 are arranged covers the construction area 21, a step of display controlling for controlling the display device 18 so as to display the building material arrangement diagram 3A and the construction area 21 of the base diagram 2 in an overlapping manner, a step of editing for performing an editing process of deleting a part of the building material group 3 in the building material arrangement diagram 3A in a unit of a building material according to the assignment from the outside, a step of counting for obtaining the number of building materials 31 constituting the building material group 3 in the building material arrangement diagram 3A, and a step of outputting for outputting the number of building materials 31 to the outside. In addition, the step of editing may further perform an ending process such as adding, deleting, changing, moving of the building material 31 in one unit for a part or all of the building material group 3.

### (Outline of a Building Material Estimation System: Management Server)

In the building material estimation system 1, the processing units 11 to 19 are connected in a wire or wireless manner so that data communication is possible. Part or all of the processing units 11 to 19 may be connected via the Internet. Each of the processing units 1 to 19 may be mounted on one information processing apparatus, or may be mounted on a plurality of information processing apparatuses in a distributed state.

For example, as shown in FIG. 3, in the building material estimation system 1, all the processing units 1 to 19 may be mounted on the management server 22 which is one information processing apparatus. More specifically, the management server 22 of the building material estimation system 1 includes a base storage device 221 (database unit) that stores the base diagram 2 including the construction area 21 in which the building materials 31 are arranged, a communication device 222 that accesses external terminals 23A to 23D, and a controller 223. The controller 223 performs a base diagram acquiring process for acquiring the base diagram 2 from the base diagram storage device 221, an arrangement diagram generating process for generating the building material arrangement diagram 3A which is formed in such a way that the building material group in which a plurality of building materials 31 are arranged covers the construction area 21, a display controlling process for controlling the external terminals 23A to 23D so as to display the building material arrangement diagram 3A and the construction area 21 of the base diagram 2 in an overlapping manner, an editing process for deleting a part of the building material group 3 in the building material arrangement diagram 3A in a unit of a building material according to an assignment from the external terminals 23A to 23D, a counting process for obtaining the number of building materials 31 constituting the building material group 3 in the building material arrangement diagram 3A, and an output process for outputting the number of building materials 31 to the external terminals 23A to 23D. In this case, the management server 22 can transmit the performing result of the editing process or the like to the external terminals 23A to 23D, and the performing result can be confirmed on display devices 231 of the external terminals 23A to 23D. Moreover, in this case, the external terminals 23A to 23D can function as the external device 19. The management server 22 includes the memory 55 shown in FIG. 1A.

In addition, the building material estimation system 1 can be configured so that a part of the processing units 11 to 19 is mounted on the external terminals 23C and 23D, and the editing process that places a heavy load on the computer may be executed in the management server 22 through the cooperative processing between the external terminals 23C and 23D and the management server 22, and the performing result may be confirmed in the external terminals 23C and 23D. For example, in the external terminal 23C, the controller 232 performs the base diagram acquiring process, the arrangement diagram generating process, the display controlling process, the editing process, the counting process, and the output process, and for other processes, an estimation process can be performed by accessing the management server 22. In addition, in the external terminal 23D, the controller 232 performs the display controlling process, the editing process, the counting process, and the output process, and for other processes, an estimation process can be performed by accessing the management server 22. Here, examples of the external terminals 23A to 23D include a general stationary and portable information processing apparatus and portable terminal devices such as a smartphone.

### (Building Material Estimation System: Editing Process)

Detailed description will be given for the editing process such as adding, deleting, changing, and moving performed for each building material.

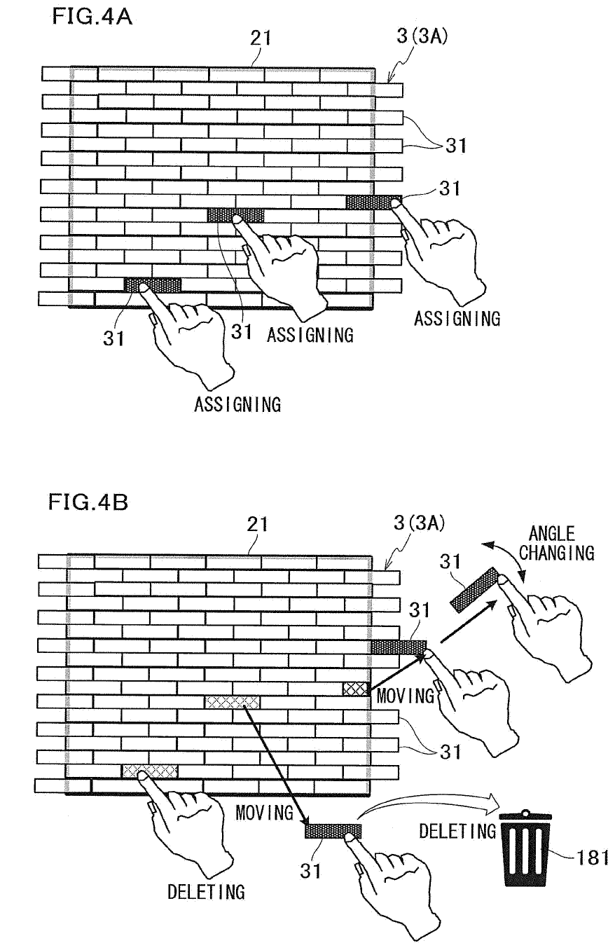

FIG. 4A and FIG. 4B illustrate an editing process in which a part (single building material 31) of the building material group 3 in the building material arrangement diagram 3A is deleted in a unit of a building material according to an assignment from the outside. In addition, the assignment from the outside may be assigned by an icon operated by a mouse, or may be assigned by touching a touch panel provided on a display screen of the building material arrangement diagram 3A by an operator. In the deleting method, the building material 31 to be deleted is assigned, and the deleting is performed by pressing a delete button (not shown) at an assigned position, and the building material 31 is moved from the assigned position by dragging towards the outside of the building material arrangement diagram 3A, and thus it is deleted by moving into a trash box icon 181 that appears when moving. In addition, the deleting may be performed in response to a click detection of the building material 31 to be deleted. Specifically, when a click on the building material 31 to be deleted is detected, the deleting of the building material 31 is completed, and the display state of the building material 31 is switched to the non-display state, so that the deleting of the building material 31 is notified. Further, when a click is detected again at the position of the deleted building material 31, the deleted building material 31 returns to its original state, and the restoration of the building material 31 is notified by switching the non-display state of the building material 31 to the display state. That is, the building material 31 is repeatedly deleted (not displayed) and revived (displayed) by repeating one click detection.

The number of deleted building materials 31 is subtracted from the total number of building materials 31 constituting the building material arrangement diagram 3A, and the total number of building materials 31 after deleting is displayed on the screen. In addition, the number of deleted building materials 31 may be displayed on the screen together with the total number of building materials 31 after deleting. The screen display is preferably displayed in a manual input column indicating that the deleting is performed by a “manual input”. In this case, there is an effect that it is easy to confirm when looking back at data including the total number of building materials 31 and the number of deleted materials.

It is preferable that the assigned building material 31 is highlighted so as to be easily identified by the operator. The highlighting is a display state that is different from the building material 31 by one or more combinations of color, brightness, and pattern. Moreover, it is preferable that the area after the deletion of the building material 31 is highlighted by a display state different from the assigned building material 31 so that the determination may be easy for the operator.

In addition, it is preferable that the assigned building material 31 can be changed in angle at an assigned position and can be changed in angle at a predetermined position after movement. Thereby, the building material 31 deleted from the assigned position can be completely deleted by the trash box icon 181, temporarily held outside the building material arrangement diagram 3A, or moved to another position of the building material group 3 as necessary.

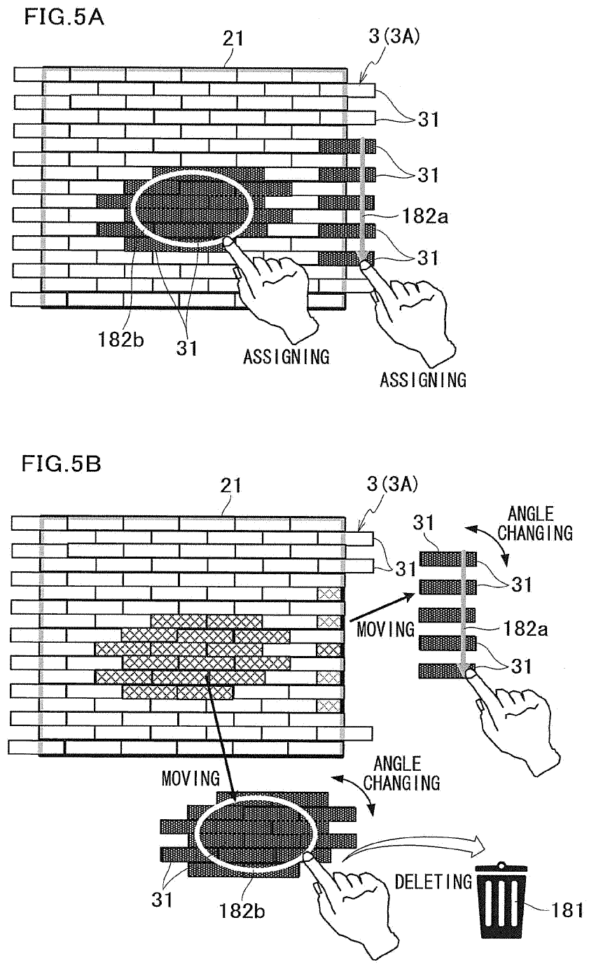

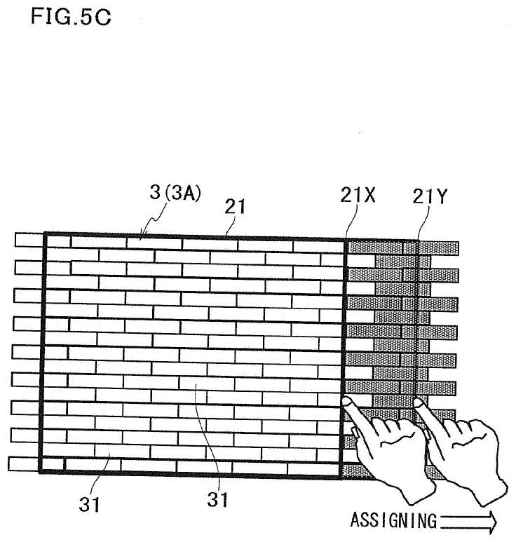

FIG. 5A and FIG. 5B illustrate an editing process in which a part (a plurality of building materials 31) of the building material group 3 in the building material arrangement diagram 3A is deleted in a unit of a building material according to an assignment from the outside. The assigning method can be performed by dragging linearly while maintaining the assigned state from the first assigned position. In this case, it is possible to assign a plurality of building materials 31 existing in a linear assigned range 182a from the first assigned position to the last assigned position. In addition, the assigned range 182a may be either linear or curved. In addition, the assigned range 182a is preferably highlighted.

When the first assigned position and the last assigned position are dragged so as to coincide with each other to make an assigned range 182b of a shape having an area (circular shape, polygonal shape, etc.), a plurality of building materials 31 existing in the area surrounded by the assigned range 182b and the assigned range 182b can be assigned. Then, after the plurality of assigned building materials 31 are highlighted, all the assigned building materials 31 are deleted at the assigned positions, or moved collectively and completely deleted by the trash box icon 181, or temporarily held and changed in angle.

In addition, as shown in FIG. 5C, instead of assigning the building material 31, when the construction area 21 is assigned as an enlargement/reduction target and dragged in a horizontal direction, a vertical direction, or a diagonal direction, the building material 31 is added and deleted with being matched to the construction area 21 after the dragging, and thereby, the building material group 3 can be rearranged. In this case, when a plurality of construction areas 21 overlap, the construction area 21 to be enlarged/reduced is enlarged or reduced and the building material group 3 is rearranged, and at the same time, the rearrangement of the building material group 3 in the remaining construction area 21 is also performed.

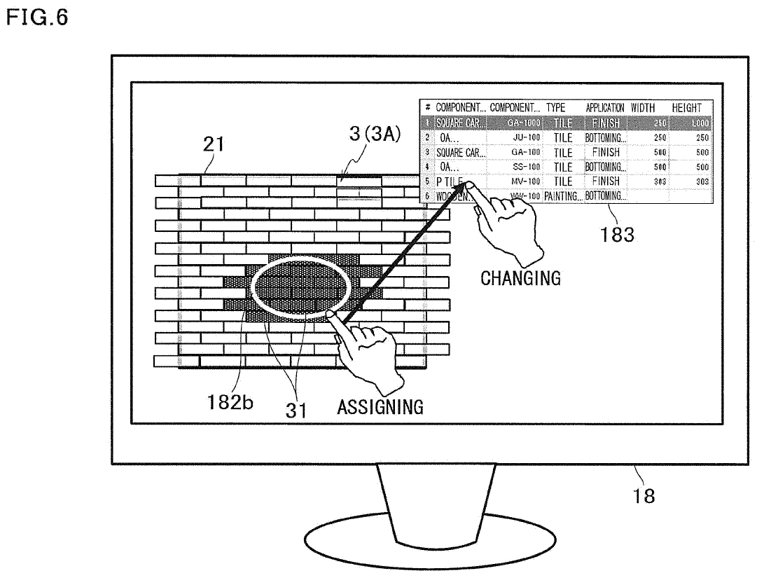

FIG. 6 illustrates an editing process for changing the assigned building material 31 to another type. More specifically, for example, a plurality of building materials 31 are assigned by an elliptical assigned range 182b, and a type list 183 is displayed on the screen by operating a type change button (not shown). Then, by clicking (pressing operation) a display column for the name of the component to be changed (P tile or the like) in the type list 183, the assigned plurality of building materials 31 can be changed to the type to be changed at once. Note that the type list 183 is scrollable in a vertical direction when the number of types of components is larger than the number displayed in the display column. Further, the type can be changed even after temporary hold or angle change.

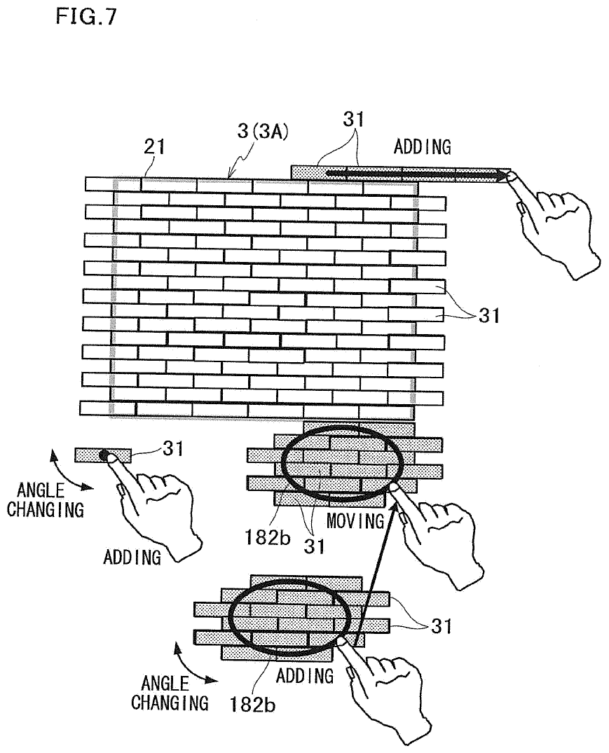

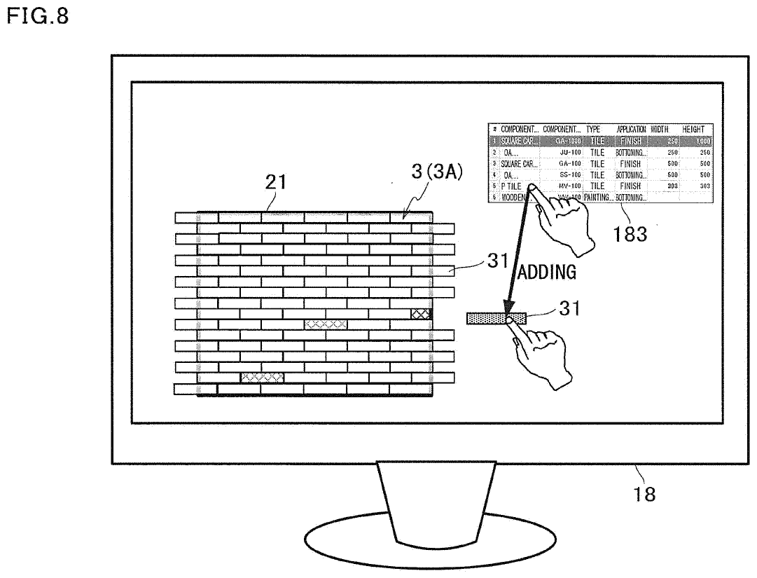

FIG. 7 illustrates an editing process for adding a building material 31 to a position assigned from the outside in the building material arrangement diagram 3A. More specifically, the adding method is performed by pressing an addition button (not shown) at an assigned position, and the addition button is operated after the linear assigned range 182a and the circular assigned range 182b are formed to add a plurality of building materials 31 at once. Also, as shown in FIG. 8, the type list 183 is displayed on the screen by operating the addition button, and the assigned type of building material 31 is added by assigning the component name and dragging it outside the type list 183. In addition, the added building material 31 can be changed in angle, moved, and changed.

The number of added building materials 31 is added into the total number of building materials 31 constituting the building material arrangement diagram 3A, and the total number of building materials 31 after adding is displayed on the screen. In addition, the number of added building materials 31 may be displayed on the screen together with the total number of building materials 31 after adding. The screen display is preferably displayed in a manual input column indicating that the adding is performed by a “manual input”. In this case, there is an effect that it is easy to confirm when looking back at data including the total number of building materials 31 and the number of added materials.

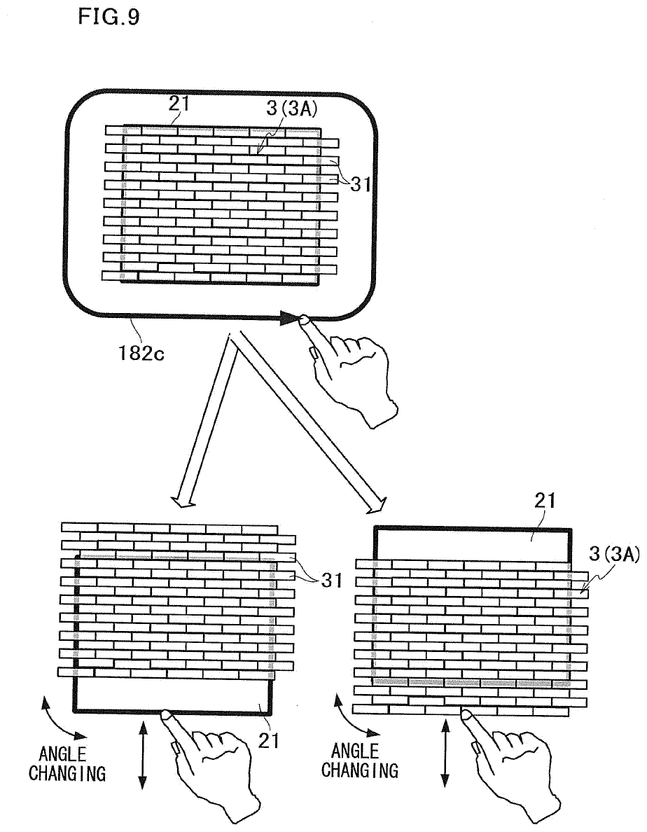

FIG. 9 illustrates an editing process in which the building material arrangement diagram 3A displayed on the display device 18 and the construction area 21 in the base diagram 2 are relatively moved by an external operation. Relative movement means movement in an up/down/left/right direction or any direction in a predetermined size unit (such as a pixel unit of the image of the display device 18). In this case, the editing work can be easily performed by relatively moving the building material arrangement diagram 3A and the construction area 21 of the base diagram 2 displayed on the display device 18 by the operation from the outside.

Specifically, the assigned range 182c is formed so as to surround the base diagram 2 and the building material arrangement diagram 3A. Thereafter, the base diagram 2 or the building material arrangement diagram 3A is assigned and dragged to move the assigned base diagram 2 or the building material arrangement diagram 3A. Moreover, an angle the assigned base diagram 2 or building material arrangement diagram 3A can be changed. In addition, when the building material arrangement diagram 3A is assigned by the assigned range 182c, the type of all the building materials 31 can be changed.

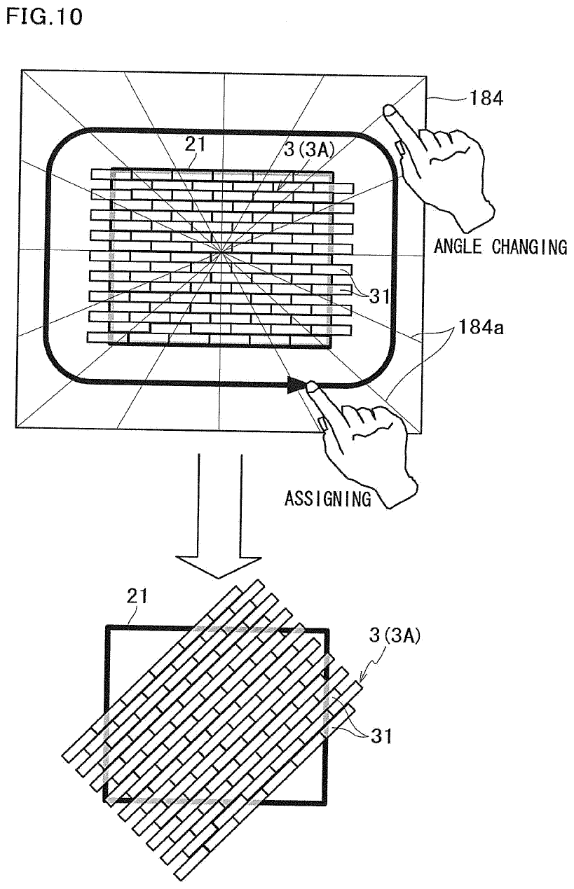

Here, when the angle is changed, as shown in FIG. 10, it is preferable that an angle change screen 184 having a plurality of angle change lines 184a such as 30 degrees and 45 degrees with respect to a horizontal line is displayed in an overlapping manner. The angle change line 184a can automatically change the building material arrangement diagram 3A to an angle corresponding to the angle change line 184a through assigning the angle change line 184a to be changed by pressing or the like. In addition, the angle change line 184a may be displayed in an overlapping manner when the angle is changed in a unit of a building material.

### (Avoidance Assigning of Building Material Estimation System)

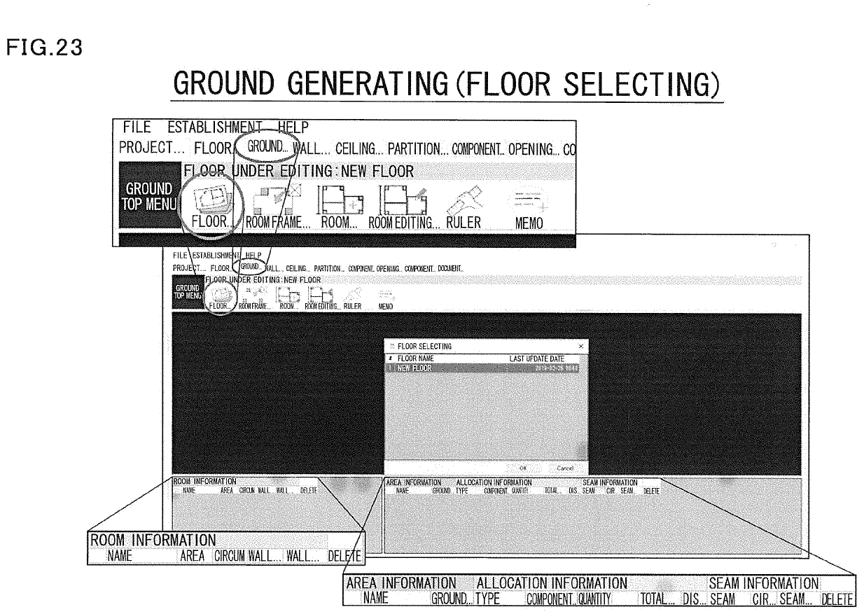

As shown in FIG. 1A, FIG. 1F, and FIG. 1G, the building material estimation system 1 comprises the avoidance assigning unit 20 in which the arrangement avoidance area 211 in which the building materials 31 are not arranged is assigned from the outside in the construction area 21 of the base diagram 2, and it is preferable that the arrangement diagram generating unit 13 generates the building material arrangement diagram 3A which is formed in such a way that the building material group 3 covers the construction area 21 except the arrangement avoidance area 211. In this case, the arrangement of the building materials 31 with respect to pillars and an atrium can be automatically avoided by setting the pillars and the atrium in the construction area 21 as the arrangement avoidance area 211, so that the editing work can be easily performed. Details of the operation of the avoidance assigning unit 20 will be described in the ground generating process of FIG. 23 to FIG. 28.

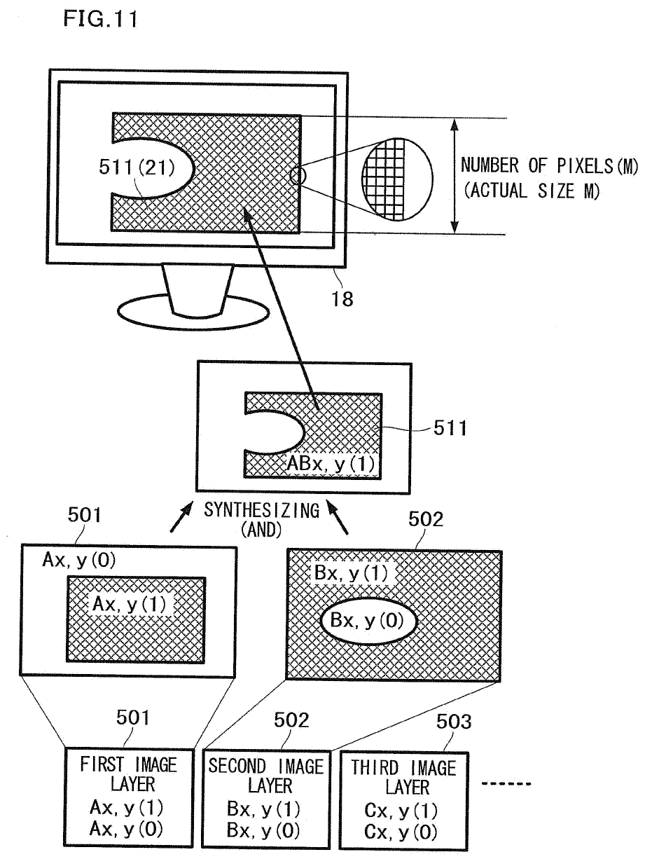

An example of the principle of the avoidance method of the building material 3 with respect to the arrangement avoidance area 211 will be described with reference to FIG. 11, and a memory area corresponding to the building material arrangement diagram 3A is divided into a plurality of image layer areas (a first image layer 501, a second image layer 502, a third image layer 503, etc.). For example, a plurality of image layers such as the first image layer 501 and the second layer 502 are classified using a set of images to be avoided or a set of images not to be avoided as a unit. For example, for the first image layer 501, an arbitrary display position on the display device 18 is indicated by Ax, y in a pixel unit, and display information Ax, y (0) can be set in the area to be avoided, while display information Ax, y (1) can be set in the area not to be avoided. Similarly, in other image layers such as the second image layer 502 and the third image layer 503, display information can be set in the avoidance area and the non-avoidance area.

Next, in the first image layer 501, the display information Ax, y (1) is set in a non-avoidance area such as a ground, and the display information Ax, y (0) is set as an avoidance area in other areas. In addition, in the second image layer 502, the display information Ax, y (0) is set in an avoidance area such as a pillar, and the display information Ax, y (1) is set as a non-avoidance area in other areas. Then, the first image layer 501 and the second image layer 502 are synthesized, and an AND operation is performed to the display information of both the layers 501 and 502, so that a synthesized image 511 having the display information ABx, y (1), which is formed by removing the avoidance area such as a pillar of the second image layer 502 from the non-avoidable area such as a ground of the first image layer 501, can be formed. The synthesized image 511 is displayed on the display device 18 by being output to a video memory. In addition, the construction area 21 is formed by a boundary line between the display information ABx, y (1) and the display information ABx, y (0).

In addition, the display position Ax, y of the first image layer 501 and the like are set in a unit of a pixel which is a display unit of the display device 18. Thereby, in the synthesized image displayed on the display device 18, if a size range is assigned and an actual size corresponding to the size range is input, the actual size such as the base diagram 2 and the building material arrangement diagram 3A displayed on the screen can be obtained according to the relationship between the number m of pixels existing in the size range and the actual size M of the size range. In addition, the display unit for obtaining the actual size may be other than pixels.

According to the above configuration, as shown in FIG. 1A, FIG. 1F, and FIG. 1G, a building material estimation device (the building material estimation system 1) that obtains the number of building materials 31 arranged in the construction area 21 of a building can be obtained. Specifically, the building material estimation device includes a memory 55 that stores various data including data related to the number of building materials 31, and a controller. The controller performs a base diagram acquiring process (the base diagram acquiring unit 12) for acquiring a base diagram and stores it in the memory 55, a construction area setting process (the construction area setting unit 53) for setting the construction area 21 in which the building materials 31 are arranged in the base diagram 2 stored in the memory 55 by the operation of the external device 19, an avoidance assigning process (the avoidance assigning unit 20) for assigning the arrangement avoidance area 211 where the building materials 31 are not arranged in the base diagram stored in the memory 55 by operating the external device, a construction area changing process (the construction area changing unit) in which a first layer for storing the construction area 21 as a true value (1) and storing the area other than the construction area 21 as a false value (0) and a second layer for storing the arrangement avoidance area 211 as a false value (0) and storing the area other than the arrangement avoidance area 211 as a true value (1) are set in the memory 55, an AND operation is performed to the first layer and the second layer, and thus an area overlapping the construction area 21 with the arrangement avoidance area 211 is set as the arrangement avoidance area 211, an arrangement diagram generating process (the arrangement diagram generating unit 13) for unfolding the building material group 3 in which the building materials 31 are arranged in the memory 55 and generating the building material arrangement diagram which is formed in such a way that the building material group 3 covers the construction area 21, a display controlling process (the display controlling unit 14) for controlling the display device 18 to display the building material arrangement diagram, the construction area 21, and the arrangement avoidance area 211 in an overlapping manner, a counting process (the counting unit 16) for obtaining the number of building materials 31 constituting the building material group 3 in the building material arrangement diagram based on the building material group 3 and the construction area 21 unfolded in the memory 55, and a output process (the output unit 17) for outputting the number of the building materials 31 to the outside.

In an actual building, there may be an area where the building materials 31 are not arranged, such as windows, pillars, and doors. In this case, when the construction area 21 is set by a conventional method or system, if a pillar or the like arranged at the corner of the room or the center of the wall is present on the boundary line of the construction area 21, a process for avoiding the pillar or the like is necessary, and thus, there is a problem that it may take time to set the construction area 21. However, according to the above configuration, by performing an AND operation to the first layer that stores the construction area 21 as the true value (1) and the area other than the construction area 21 as the false value (0) and the second layer that stores the arrangement avoidance area 211 as the false value (0) and the area other than the arrangement avoidance area 211 as true value (1), an area where the construction area 21 and the arrangement avoidance area 211 overlap is set as the arrangement avoidance area 211, and thus, the construction area 21 can be easily set.

### (Unfolding Display of Building Material Estimation System)

In addition, the building material estimation system 1 preferably has a visualization function which can be used as an unfolded view by clicking three points on a part that cannot be visually confirmed on a plane, such as complicated pasting like a wall and an arrangement of openings such as window.

Specifically, as shown in FIG. 1A, the building material estimation system 1 comprises the base diagram acquiring unit 12 that acquires the base diagram 2 including a ground construction area and a wall construction area in which the building materials 31 are arranged, the arrangement diagram generating unit 13 that generates a ground building material arrangement diagram (the building material arrangement diagram 3A), which is formed in such a way that the building material group 3 in which the building materials 31 are arranged covers the construction area 21, and generates a wall building material arrangement diagram (the building material arrangement diagram 3A), which is formed in such a way that the building material group 3 covers the wall construction area, the display controlling unit 14, the editing unit 15 that performs an editing process such as deleting a part of the building material group 3 in the ground building material arrangement diagram and the wall building material arrangement diagram in a unit of a building material according to the assignment from the outside, the counting unit 16 that determines the number of building materials 31 constituting the building material group 3 in the ground building material arrangement diagram and the wall building material arrangement diagram respectively, and the output unit 17 that outputs the number of the building materials 31 to the outside.

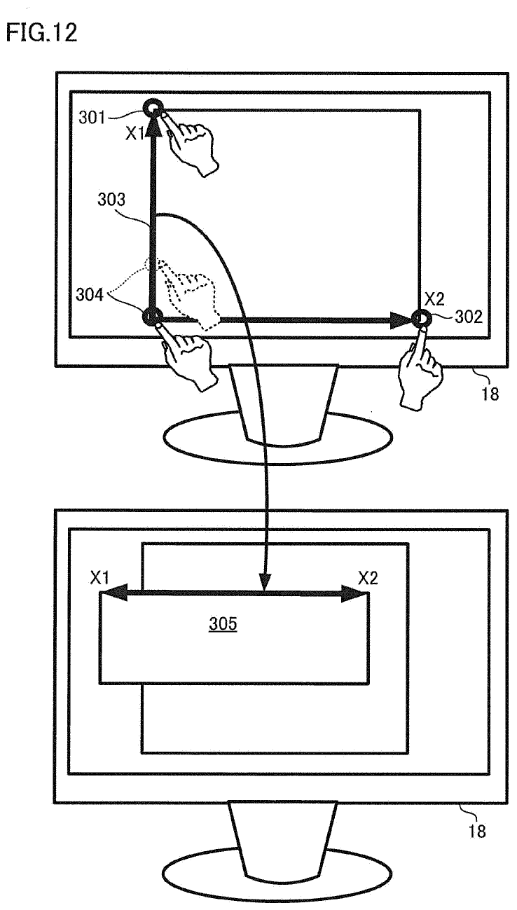

As shown in FIG. 12, the display controlling unit 14 makes it possible to assign two reference points 301 and 302 on the wall and one direction point 304 (solid line position or broken line position) from the outside, and controls the display device 18 so as to display the wall construction area in the range on the area line 303 connecting the reference points 301 and 302 with each other and including the direction point 304 as an unfolded view.

### (Unfolding Display of Building Material Estimation System: Display Method)

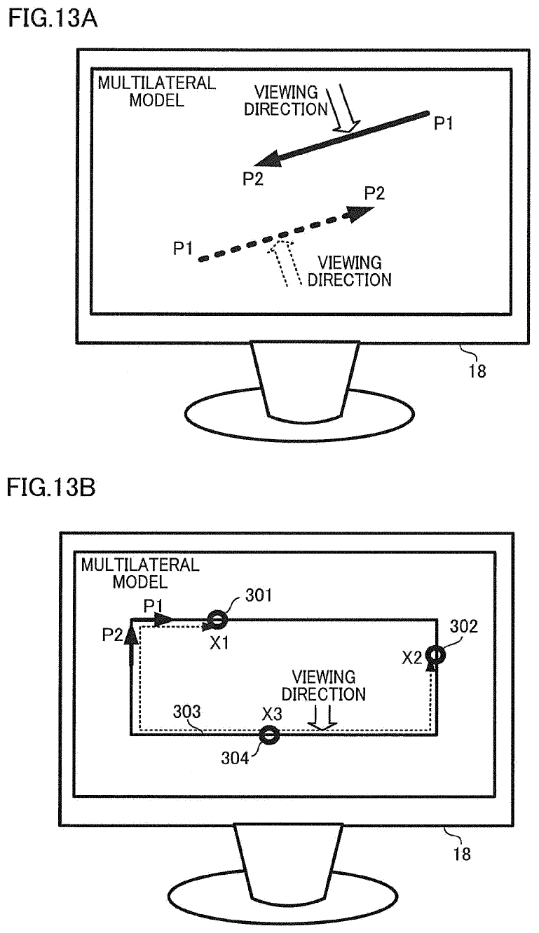

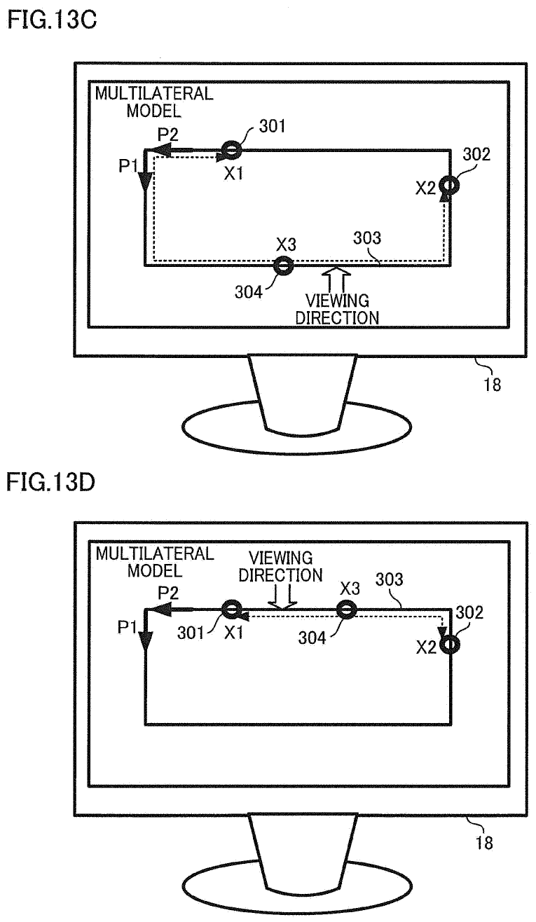

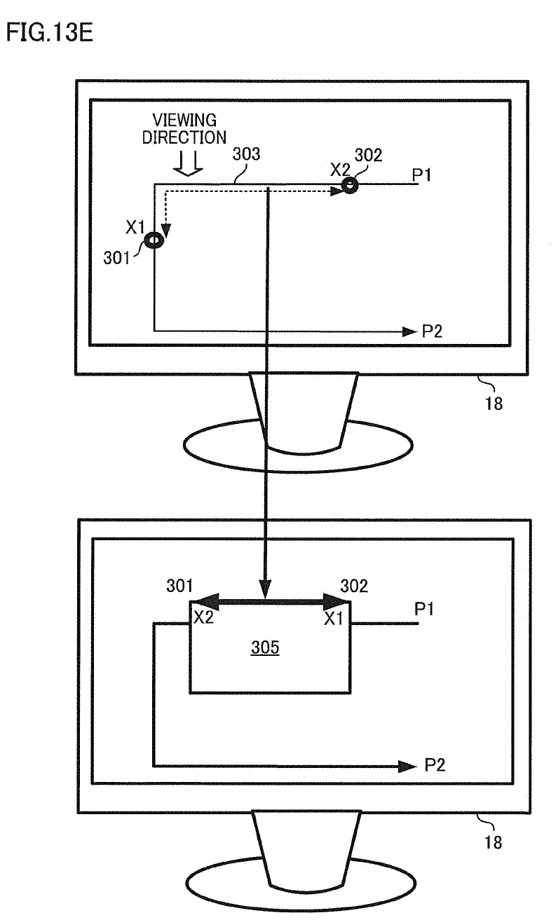

As shown in FIG. 13A, in a polygon mode in which a wall is drawn by bending a straight line, a viewpoint position is set on the right side with respect to a drawing direction (solid line or broken line) from a drawing start position P1 to a drawing end position P2, and an unfolded view in a viewing direction from the viewpoint position toward the drawing direction is created. Furthermore, in the case of a square mode or a circle mode in which a room whose periphery is closed is drawn with a square or a circular wall, an unfolded view in a viewing direction from the inside to the outside of the room is created.

For example, FIG. 13B indicates a state that, in the polygon mode, a rectangular room is formed by drawing in an arrow direction (clockwise drawing direction) from the drawing start position P1 and connecting the drawing end position P2 to the drawing start position P1. In this case, since the right side of the drawing direction arrow direction is the viewpoint position, the viewing direction is set from the inside to the outside of the room. In addition, when the two reference points 301 and 302 (X1 and X2) and one direction point 304 (X3) on the wall are assigned from the outside, a range on the area line 303 connecting the reference points 301 and 302 with each other and including the direction point 304 is displayed as an unfolded view in the viewing direction. Moreover, in the case of a room, it is preferable that an unfolded view of the entire room is displayed by assigning one reference point 301 (X1) on the wall surface and then right-clicking.

For example, FIGS. 13C and 13D indicate a state that, in the polygon mode, a rectangular room is formed by drawing in an arrow direction (anticlockwise drawing direction) from the drawing start position P1 and connecting the drawing end position P2 to the drawing start position P1. In this case, since the right side of the drawing direction is the viewpoint position, the viewing direction is set from the outside to the inside of the room. In addition, when the two reference points 301 and 302 (X1 and X2) and one direction point 304 (X3) on the wall are assigned from the outside, a range on the area line 303 connecting the reference points 301 and 302 with each other and including the direction point 304 is displayed as an unfolded view in the viewing direction.

For example, FIG. 13E indicates a state that, in the polygon mode, a ⊐ shaped wall is formed by drawing in an arrow direction (anticlockwise drawing direction) from the drawing start position P1 and separating the drawing end position P2 from the drawing start position P1. In this case, since the right side of the drawing direction is the viewpoint position, the viewing direction is set from the outside to the inside of the wall. In addition, when the two reference points 301 and 302 (X1 and X2) on the wall are assigned from the outside, a range on the area line 303 connecting the reference points 301 and 302 with each other, even without including the direction point 304, is displayed as an unfolded view in the viewing direction.

### (Herringbone Counting Method for Building Material Estimation System)

The counting method of the building material 31 when the building material group 3 is arranged in herringbone will be described in detail.

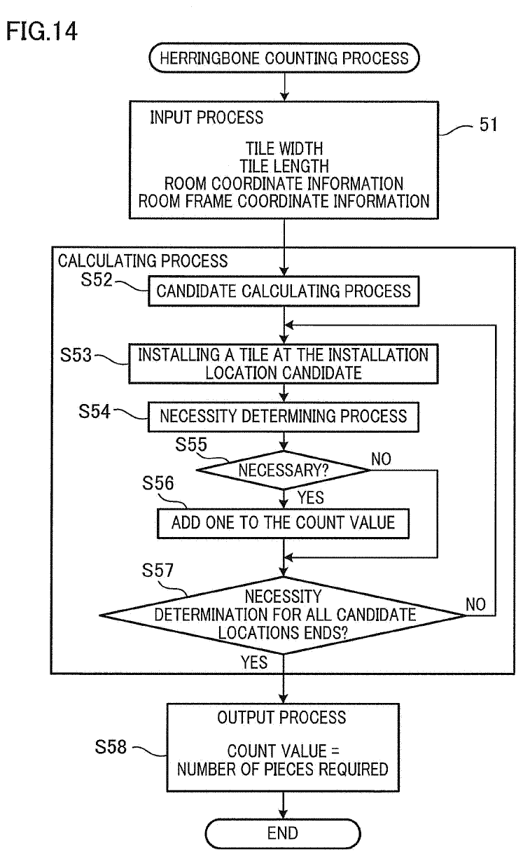

As shown in FIG. 14, in the herringbone counting process, an input process is performed (S51). Specifically, a tile width and a tile length as the building material 31, room coordinate information of the construction area 21, and frame coordinate information that becomes the non-allocated area 24 are input.

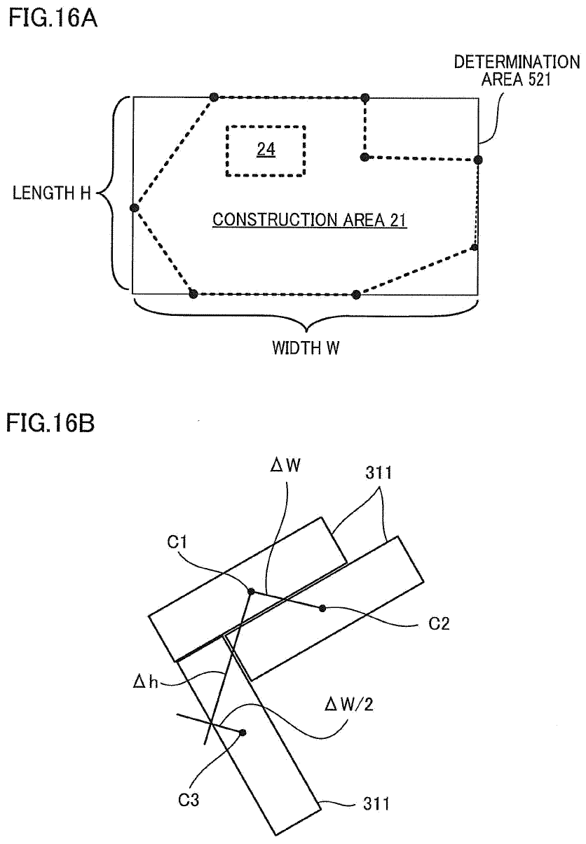

Next, a calculating process is performed. Specifically, first, a candidate calculating process is performed (S51). The candidate calculating process will be described, and as shown in FIG. 16A, a rectangular determination area 521 in which room coordinates completely fit is calculated. The horizontal (X direction) width of the determination area 521 is W, and the vertical (Y direction) width is H. As shown in FIG. 16B, when the dimensions of the tile 311 are the width w (mm), the height h (mm), and the joint width m (mm), the position of the center point of the tile 311 arranged in the herringbone is determined in the determination area 521. That is, in the case of w>h, Δw in the horizontal direction and Ah in the vertical direction from the starting point of the determination area 521 are obtained by (Equation 1) and (Equation 2). Then, the center points C1, C2, C3, . . . are obtained as installation location candidates based on the positional relationship shown in FIG. 16B.

Δw=(h+m)×√2 (Equation 1)

Δh=(h/2+m)×√2 (Equation 2)

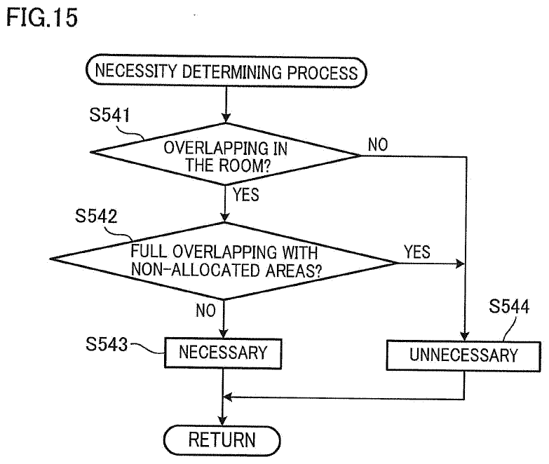

When all the installation location candidates in the determination area 521 are calculated, the tile 311 is installed for the installation location candidates (S53). A necessity determining process is performed on the installed tile 311 (S54). Specifically, as shown in FIG. 15, it is determined whether there is an overlap in the construction area 21 (S541). If there is no overlap (S51: NO), an unnecessary flag is set (S544). On the other hand, when there is an overlap in the construction area 21 (S51: YES), it is then determined whether or not it completely overlaps with the non-allocated area 24 (S542). If they completely overlap (S542: YES), an unnecessary flag is set (S544). If they do not completely overlap (S542: NO), a necessary flag is set (S543).

Next, based on the flag information in the necessity determining process, it is determined whether or not the tile 311 is necessary (S55). If necessary (S55: YES), after the counter value is incremented by 1 (S56), it is determined whether the necessity determination of the tile 311 for all the installation location candidates is completed (S57). If not completed (S57: NO), the process is reperformed from S53, and when the necessity determination the tile 311 for all the installation location candidates is completed (S57: YES), the output process is performed and the counter value is output as the required number of the tiles 311 (S58).

As described above, in the case where the building material 31 is arranged in herringbone, the counting unit 16 according to the present embodiment can obtain the number of the building materials 31 arranged in the construction area 21 by performing the following processes: determining a regular square-shaped determination area 521 surrounding the construction area 21 and unfolds it in the memory; in the determination area 521, determining the position of the center point of all the building materials 31 when the building material group 3 in which the building materials 31 are arranged in herringbone is overlapped in the determination area 521, and setting it an installation location candidate; determining whether or not each of the building materials 31 in the installation location candidate is overlapped in the construction area 21, and determining the number of overlapped building materials 31.

In other words, the building material estimation device (the building material estimation system 1) for the herringbone comprises the counting unit 16 that obtains a regular square-shaped determination area 521 in which the construction area 21 is completely accommodated, determines the position of the center point of the building material 31 arranged in herringbone as an installation location candidate in the determination area 521, unfolds the building materials 31 in the memory 555 for all the installation location candidates in the determination area 521, and calculates the number of building materials 31 that overlap in the construction area 21.

Thereby, conventionally, since there is no configuration in which building materials are arranged in a herringbone arrangement, the number of building materials in a herringbone arrangement cannot be obtained; however, according to the above configuration, the number of building materials in a herringbone arrangement can be obtained.

Furthermore, the counting unit 16 determines whether or not each building material 31 arranged in the installation location candidate completely overlaps with the non-allocated area 24, respectively, and subtracts the number of overlapped building materials 31 from the number of the building materials 31 arranged in the construction area 21, by which the number of building materials 31 can be obtained even when the non-allocated area 24 exists in the construction area 21.

In other word, as shown in FIG. 1G, the building material estimation device (the building material estimation system 1) for the herringbone comprises the counting unit 16, in which according to the building material group 3, the construction area 21, and the arrangement avoidance area 211 unfolded in the memory 55, the number of constructions of the building materials 31 which at least overlap partially in the construction area 21 and the number of avoidances of the building materials 31 included completely in the arrangement avoidance area 211 are determined, and the number of avoidances is subtracted from the number of constructions, by which the number of building materials 31 is obtained. According to the above configuration, the number of building materials 31 can be obtained correctly by subtracting the number of avoidances from the number of constructions.

### (Building Material Estimation System: Drawing Function)

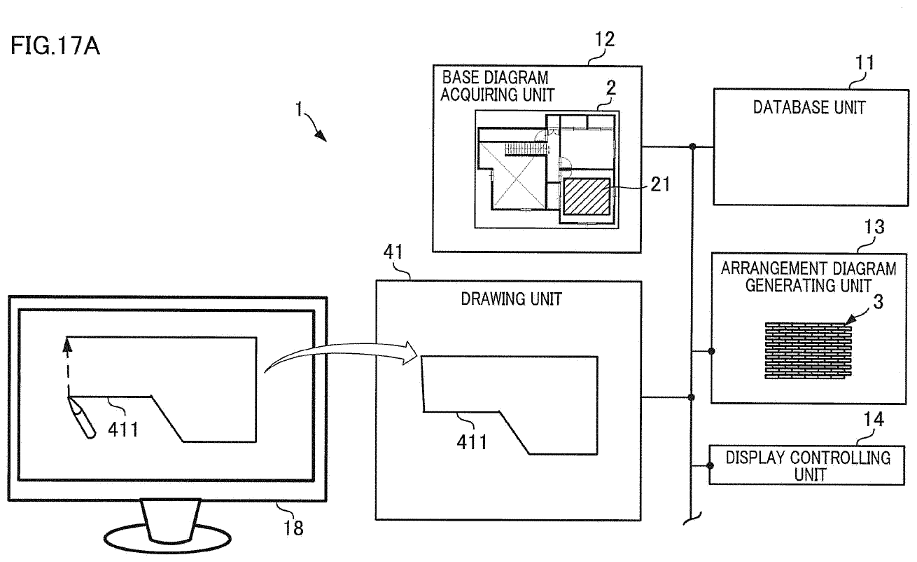

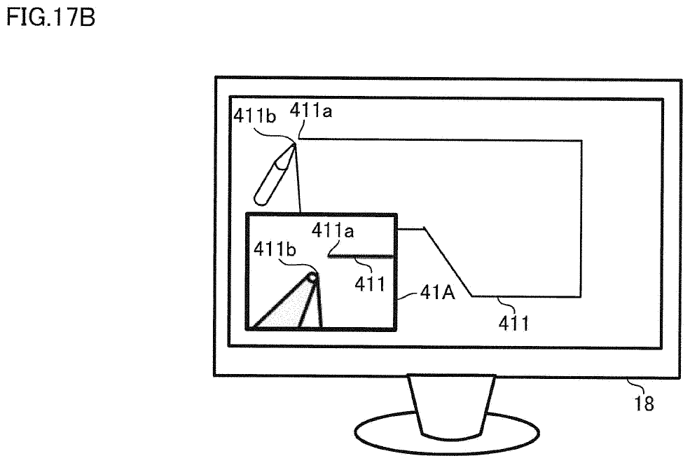

As shown in FIG. 17A, it is preferable that the building material estimation system 1 has a drawing function that enables manual drawing by mouse operation or touch panel touch operation. The drawing function makes it possible to add a design diagram to a blank screen. Thereby, for example, a corridor can be measured and made into a drawing in the field.

As shown in FIG. 17B, it is preferable that the building material estimation system 1 has a magnifying glass function for enlarging and displaying an input area including a manual input location. The input area corresponds to a preset magnification and a screen size of the enlarged display screen 41A, and is determined in such a way that the input location is the center of the screen. As a result, for example, when the end portions 411a and 411b of the diagram 411 approach each other during the drawing by the diagram 411, the end portions 411a and 411b can be easily connected by drawing while viewing the enlarged display screen 41A. In addition, the magnifying glass function may be switched by operating an on/off button in “scale” associated with “floor generating”.

In addition, the magnifying glass function may be automatically performed when the drawing function is performed, or may be switched between the performing state and the stop state by a switching operation. Further, it is preferable that the enlargement condition can be set in the performing state of the magnifying glass function. For example, in the performing state of the magnifying glass function, the enlarged display screen 41A may appear only when the condition that the end portions 411a and 411b of the enlarged display screen 41A exist in the enlarged area is satisfied. In addition, the magnifying glass function may be performed at a timing other than the execution of the drawing function. In this case, when the building material 31 or the like is assigned or a numerical value is input, the input location is enlarged and displayed, thereby facilitating operations when using an information processing apparatus such as a portable terminal having a small screen size.

The building material estimation system 1, the building material estimation method, the management server 22, and the building material estimation program in the above description perform an editing process such as adding, deleting, changing, moving the building material 31 in one unit for a part or all of the building material group 3, but is not limited thereto. That is, the building material estimation system 1, the building material estimation method, the management server 22, and the building material estimation program may, instead of or in addition to the editing process, set a plurality of construction areas 21 in which the building materials 31 are arranged in the base diagram 2, assign any one or more construction areas 21, and select a building material 31 used in the assigned construction area 21.

More specifically, as shown in FIG. 1A, the building material estimation system 1 comprises the base diagram acquiring unit 12 that acquires the base diagram 2, the construction area setting unit 53 that sets a plurality of construction areas 21 in which the building materials 31 are arranged in the base diagram 2, the building material assigning unit 54 that selects one or more of the construction areas 21 and assigns the building material 31 used in the selected construction area 21, the arrangement diagram generating unit 13 that generates the building material arrangement diagram 3A, which is formed in such a way that the building material group 3 in which the building materials 31 assigned by the building material assigning unit 54 are arranged covers the construction area 21, for all construction areas 21 selected by the building material assigning unit 54, the display controlling unit 14 that controls the display device 18 so as to display the building material arrangement diagram 3A and the construction area 21 in an overlapping manner, the counting unit 16 that obtains the number of building materials 31 constituting the building material group 3 in the building material arrangement diagram 3A generated for all construction areas 21 selected by the building material assigning unit 54 respectively, and the output unit 17 that outputs the number of building materials 31 to the outside.

In addition, the building material estimation method comprises a step of base diagram acquiring that acquires the base diagram 2, a step of construction area setting that sets a plurality of construction areas 21 in which the building materials 31 are arranged in the base diagram 2, a step of building material assigning that selects one or more of the construction areas 21 and assigns the building material 31 used in the selected construction area 21, a step of arrangement diagram generating that generates the building material arrangement diagram 3A, which is formed in such a way that the building material group 3 in which the building materials 31 assigned by the building material assigning unit 54 are arranged covers the construction area 21, for all construction areas 21 selected by the building material assigning unit 54, a step of display controlling that controls the display device 18 so as to display the building material arrangement diagram 3A and the construction area 21 in an overlapping manner, a step of counting that obtains the number of building materials 31 constituting the building material group 3 in the building material arrangement diagram 3A generated for all construction areas 21 selected by the building material assigning unit 54 respectively, and a step of output that outputs the number of building materials 31 to the outside.

In addition, as shown in FIG. 3, the management server 22 includes a base storage device 221 that stores the base diagram 2, a communication device 222 that accesses the external terminals 23A to 23D, and a controller 223 that performs a base diagram acquiring process for acquiring the base diagram 2, a construction area setting process for setting a plurality of construction areas 21 in which the building materials 31 are arranged in the base diagram 2, a building material assigning process for selecting one or more of the construction areas 21 and assigning the building material 31 used in the selected construction area 21, an arrangement diagram generating process for generating the building material arrangement diagram 3A, which is formed in such a way that the building material group 3 in which the building materials 31 assigned by the building material assigning process are arranged covers the construction area 21, for all construction areas 21 selected by the building material assigning process, a display controlling process for controlling the external terminals 23A to 23D so as to display the building material arrangement diagram 3A and the construction area 21 in an overlapping manner, a counting process for obtaining the number of building materials 31 constituting the building material group 3 in the building material arrangement diagram 3A generated for all construction areas 21 selected by the building material assigning process respectively, and a output process for outputting the number of building materials 31 to the external terminals 23A to 23D.

As shown in FIG. 2, in the building material estimation program, a computer is enabled to function as: the base diagram acquiring unit that acquires the base diagram 2, the construction area setting unit that sets a plurality of construction areas 21 in which the building materials 31 are arranged in the base diagram 2, the building material assigning unit that selects one or more of the construction areas 21 and assigns the building material 31 used in the selected construction area 21, the arrangement diagram generating unit that generates the building material arrangement diagram 3A, which is formed in such a way that the building material group 3 in which the building materials 31 assigned by the building material assigning unit are arranged covers the construction area 21, for all construction areas 21 selected by the building material assigning unit, the display controlling unit that controls the display device 18 so as to display the building material arrangement diagram 3A and the construction area 21 in an overlapping manner, the counting unit that obtains the number of building materials 31 constituting the building material group 3 in the building material arrangement diagram 3A generated for all construction areas 21 selected by the building material assigning unit respectively, and the output unit that outputs the number of building materials 31 to the outside.

According to the configuration of the building material estimation system 1, the building material estimation method, the management server 22, and the building material estimation program, one or more construction areas 21 are selected, and the building material 31 used for the selected construction area 21 is assigned, by which, after the selecting of the construction area 21 and the assigning of the building material 31 are completed in advance, the building material arrangement diagram 3A is generated for one time, and thus, it is possible to reduce assignment mistakes for building materials in each construction area 21, since reconfirmation is easier than in the case of assigning the building material 31 and generating the building material arrangement diagram 3A in each construction area 21. In addition, according to the above configuration, an area which does not have an arrangement plan is excluded from the calculation object of the required number of building materials 31 by setting some areas of the arrangement plan of the building material 31 in the base diagram 2 as the construction area 21, and therefore, the required number of building materials 31 can be obtained with high accuracy.

### (Specific Example of the Building Material Estimation System)

Next, the configuration of the building material estimation system 1 will be described specifically, which includes: a database unit 11 for storing a design diagram file including design diagram data of a building (house, edifice, etc.), a building material specification file including size data and shape data of the building material 31 (size, shape, material, product name, product number, price, etc.), a pattern file including an arrangement pattern data (grid arrangement, width shift arrangement, herringbone arrangement) of the building material 31; a base diagram acquiring unit 12 for acquiring the base diagram 2 including the construction area 21 (all or a part of the ground, wall, and ceiling surface) in which the building materials 31 are arranged according to the design diagram data of the database unit 11; a building material assigning unit for assigning the size data and shape data in the building material specification file and the arrangement pattern in the pattern file from the outside; an arrangement diagram generating unit 13 for generating the building material arrangement diagram 3A, which is formed in such a way that the building material group 3 in which the building materials 31 are arranged covers the construction area 21, according to the size data and shape data and the arrangement pattern assigned by the building material assigning unit; a display controlling unit 14 for controlling the display device 18 so as to display the building material arrangement diagram 3A and the construction area of the base diagram 2 in an overlapping manner; an editing unit 15 for performing an editing process for deleting a part of the building material group 3 in the building material arrangement diagram 3A in a unit of a building material, adding a building material 31 to a position assigned from the outside in the building material arrangement diagram 3A, according to the assignment from the outside; a counting unit 16 for obtaining the number of building materials 31 constituting the building material group 3 in the building material arrangement diagram 3A; and an output unit 17 for outputting the number of building materials 31 to the outside.

### (Specific Example of Building Material Estimation System: Tab Management)

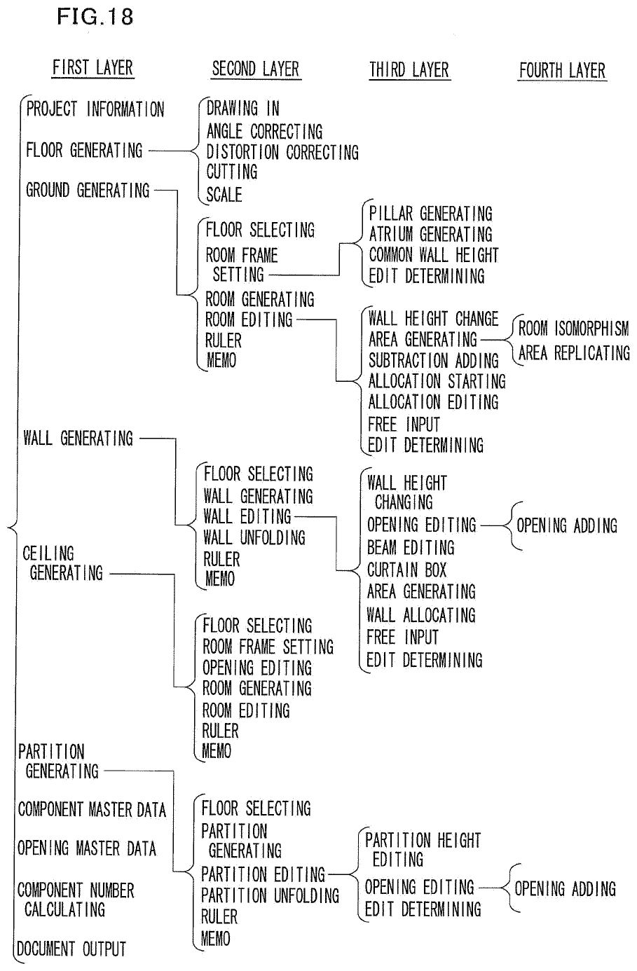

As shown in FIG. 18, the building material estimation system 1 is configured to perform detailed function processing step by step from large function processing by associating predetermined processing with tabs and icons of a plurality of layers displayed on the screen. For example, “diagram reading”, “angle correcting”, “distortion correcting”, “cutting”, and “scale” exist as the second layer associated with “floor generating” of the first layer. In addition, “floor selecting”, “room frame setting”, “room generating”, “room editing”, “ruler”, and “memo” exist as the second layer associated with “ground generating” of the first layer. Then, “wall height changing”, “area generating”, “subtraction adding”, “allocation starting”, “edit allocating”, “free input”, “edit determining” exist as the third layer associated with “room editing” of the second layer. In the “area generating” of the third layer, “room isomorphism” and “area copying” is associated thereto as the fourth layer. In addition, the hierarchical structure in FIG. 18 is an example, and there are tabs and icons associated with various functions not shown.

Specifically, the tabs of the first layer are associated with project information, floor generating, ground generating, wall generating, ceiling generating, partition generating, component master data, opening master data, component number calculating, and document output process, respectively. Here, the component master data tab corresponds to the database unit 11 and can read various information of the building material 31. The opening master data tab is associated with the processing of the avoidance assigning unit 20 described above, and can read various information on the arrangement avoidance area such as a window and a door. The component number calculation tab is associated with the counting unit 16. The document output tab makes it possible to output the purchase amount based on the unit price of building material 31 and the number of building materials 31 in addition to the function of the output unit 17. Other tabs will be described later.

### (Specific Example of Building Material Estimation System: Project Information Processing)

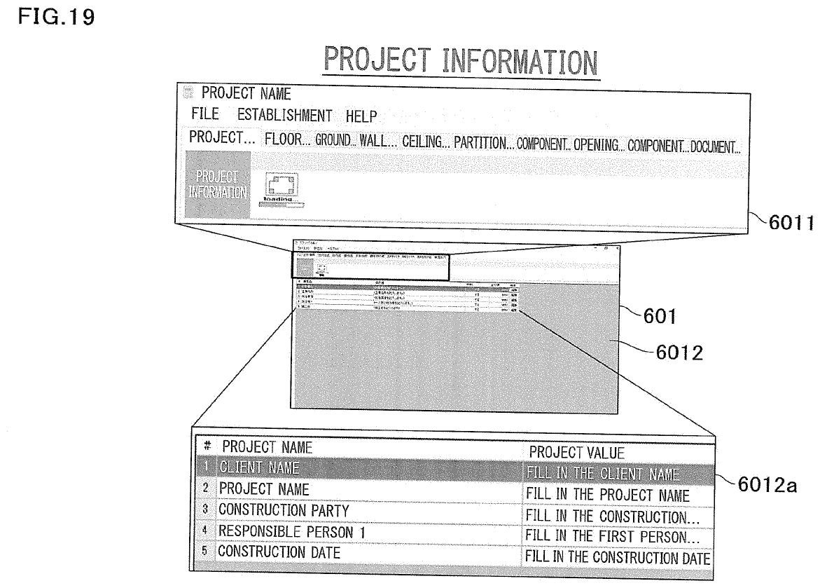

FIG. 19 shows an initial screen 601 displayed when the information processing apparatus is activated, and wherein a tab selection area 6011 for the first layer is arranged at the top of the initial screen 601 and a processing area 6012 is arranged below the tab selection area 6011. The project information processing is performed when the information processing apparatus is activated, and a registration area 6102a is displayed in the processing area 6012. In the registration area 6102a, basic information (client name, project name, etc.) can be input. In addition, by default, five items are displayed: “client name”, “construction party”, “project name”, “responsible person”, and “construction date” are displayed, but any items can be added freely.

### (Specific Example of Building Material Estimation System: Floor Generating Process)

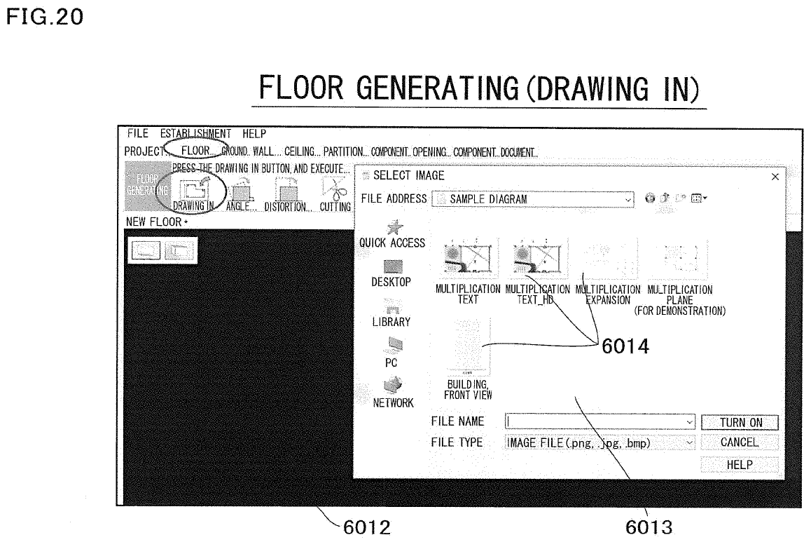

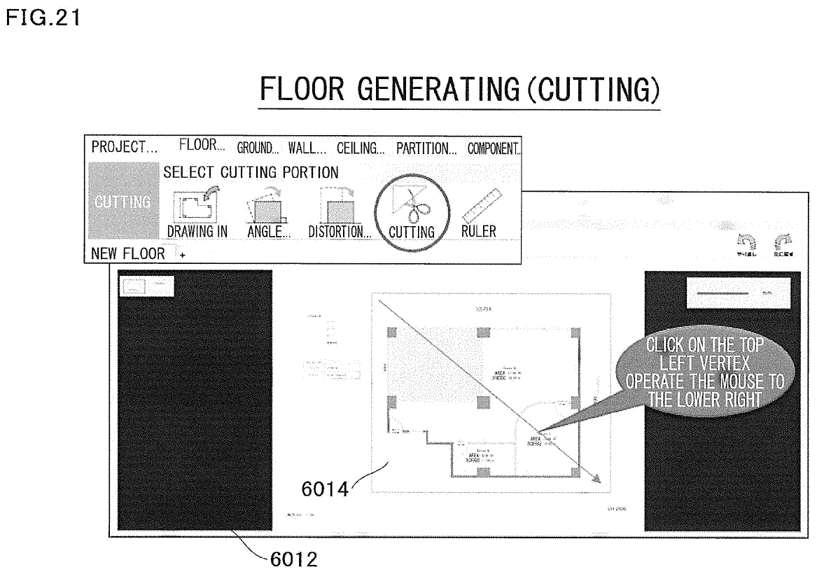

FIG. 20 is a display screen when the floor generation tab is operated. Normally, after inputting the project information, the screen moves to the floor generation tab, and a desired diagram can be read from a diagram read window 6013 displaying a list of a plurality of diagrams 6014. When the reading of the diagram is completed, the diagram 6014 is displayed in the approximate center of the processing area 6012 as shown in FIG. 21. In addition, when correcting an angle shift or distortion with respect to the diagram 6014, the correcting can be performed by operating an angle correction icon and a distortion correction icon.

Also, it is possible to cut out only a desired corresponding portion (base diagram 2) from the diagram 6014. The cutting method can perform cutting by clicking a cut icon and surrounding the corresponding part with a mouse operation. For example, the corresponding part can be surrounded by clicking the upper left vertex of the corresponding part area and operating the mouse to the lower right. Furthermore, in the following description, various assignments and operations on the display screen will be described using expressions of mouse operations, but touch operations using a touch panel may be used.

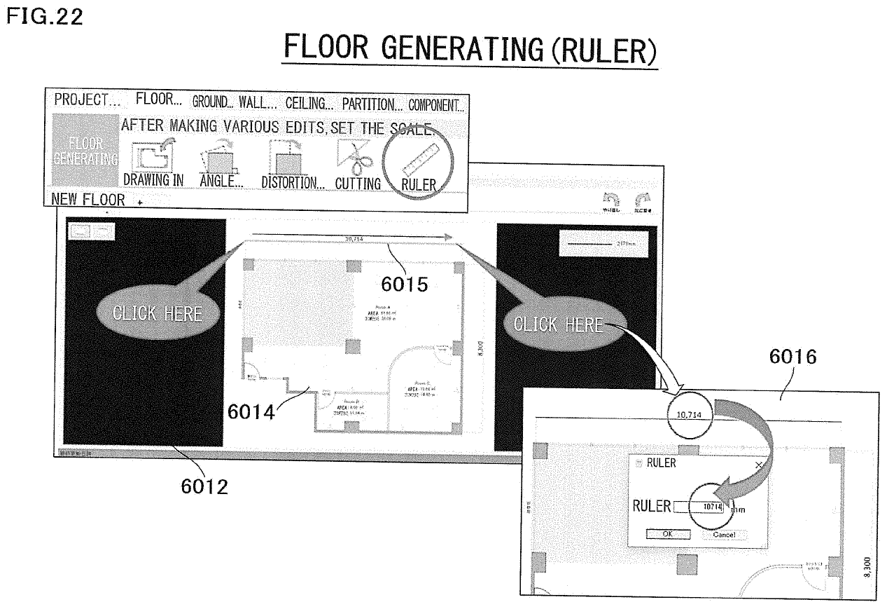

Further, as shown in FIG. 22, when a scale icon is clicked, a scale processing for calculating actual dimensions at various locations in the diagram 6014 is performed. For example, when two locations on both ends of the longest scale range 6015 on the diagram 6014 to be used as a scale reference are clicked and a scale input screen 6016 is launched, the actual dimensions of the clicked scale range, “10, 714”, can be input. As a result, the actual dimensions at various locations in the diagram 6014 are calculated based on the relationship between the actual dimensions of the scale range 6015 and the number of pixels existing in the scale range 6015.

### (Specific Example of Building Material Estimation System: Ground Generating Process)

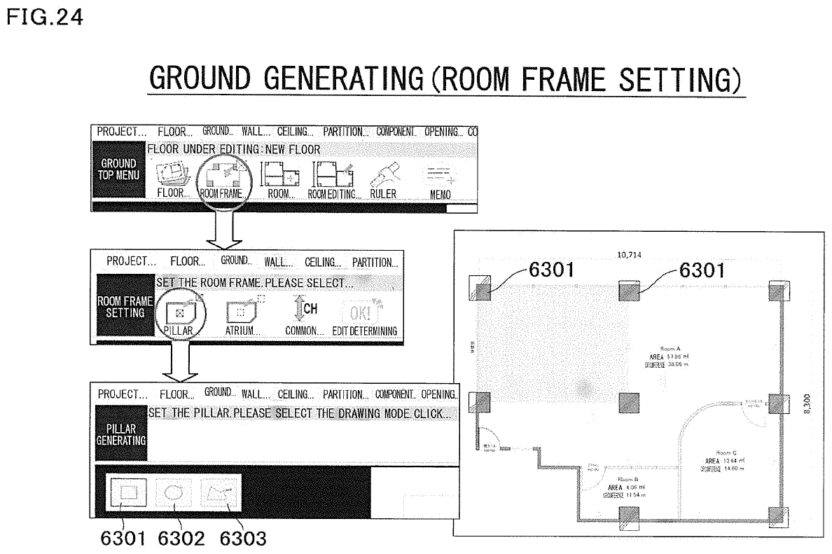

As shown in FIG. 23, when a ground generation tab is operated, a ground generating process is performed. For example, when a floor selection icon is clicked from the ground generation tab and the scaled diagram is called and displayed on the screen, the diagram is displayed in the center of the screen. Thereafter, as shown in FIG. 24, when performing a frame setting process for setting the frame position (a pillar, atrium), the pillar generating and the atrium generating can be selected by selecting a room frame set icon. When performing the pillar selection, a pillar generation icon is selected, and a square icon 6301, a circle icon 6302, and a polygon icon 6303 are displayed. In addition, one of the shape icons 6310, 6302, and 6303 is selected, and the mouse is operated so as to surround the pillar image displayed on the screen. In FIG. 24, the pillar is surrounded by a square mode performed by selecting the square icon 6301. Note that the pillar 6017 at the end of the room can be surrounded so as to protrude slightly.

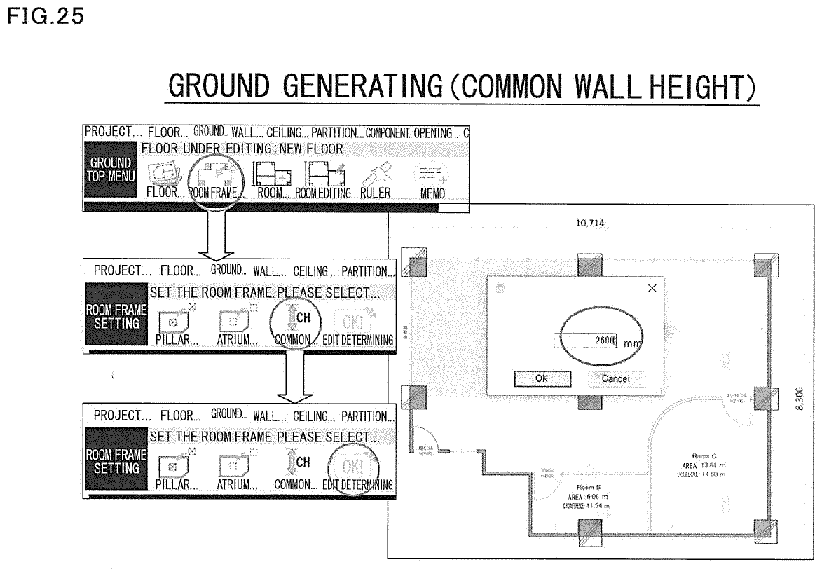

As shown in FIG. 25, after completing the “pillar generating” and “atrium generating”, a common wall height icon is clicked to enter the wall height. That is, when the common wall height icon is clicked, a wall height input window 6018 appears. Then, the common wall height is input to the input column in the wall height input window 6018 and an edit confirmation icon is clicked, thereby completing the frame setting process.

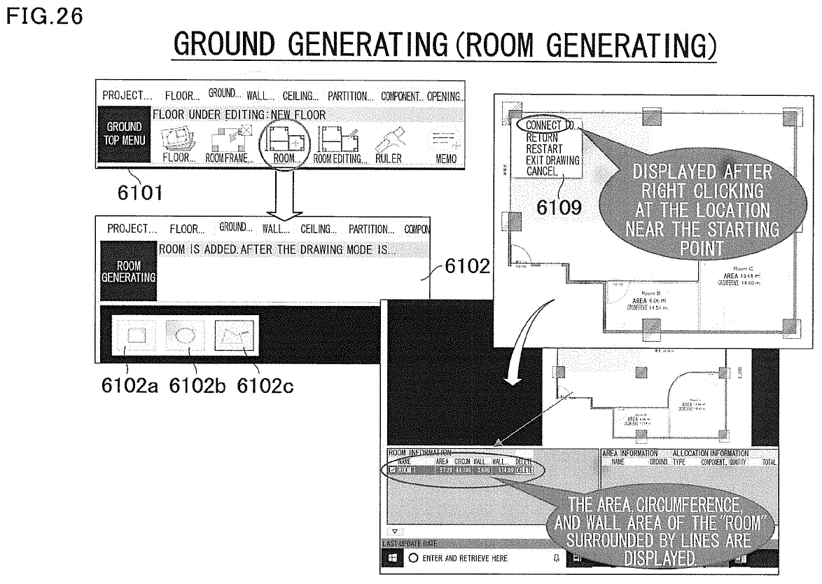

As shown in FIG. 26, when a room generation icon is operated, a room generating process for selecting a room is performed. Specifically, a room generation display unit 6102 appears by selecting the room generation icon from the icons displayed on a ground top display unit 6101. When one of the square icon 6102a, circle icon 6102b, and polygon icon 6102c is selected in the room generation display unit 6102, a room can be generated by drawing mode processing corresponding to the selected icons 6102a, 6102b, and 6102c. In addition, the default drawing mode process is polygon drawing.

Thereafter, for example, when the room generating is performed in the polygon mode, the drawing mode processing with the polygon icon 6102c is selected, and a red highlight line is drawn along the diagram by operating the mouse. Clicking at the point where it is desired to bend the highlight line, the room is drawn so that it is surrounded by the highlight line. Note that the location of the room frame is drawn along the room frame. When the highlight line reaches a location close to the starting point, right-clicking causes an auxiliary window 6019 “connect to the starting point” to appear. When “connect to the starting point” is selected, the starting point and ending point of the highlight line automatically match, the room is surrounded by the highlight line, and the area, circumference, and wall area of the entire room surrounded by the highlight line are displayed in the display column. In addition, when a room frame such as an independent pillar exists in the room, the circumference of the room frame is added to the circumference of the whole room surrounded by the highlight line, while the setting area of the room frame is subtracted from the ground area of the whole room. Further, when there is an atrium in the room, the setting area of the atrium is only subtracted from the ground area, and the circumference is maintained without affecting the circumference of the entire room.

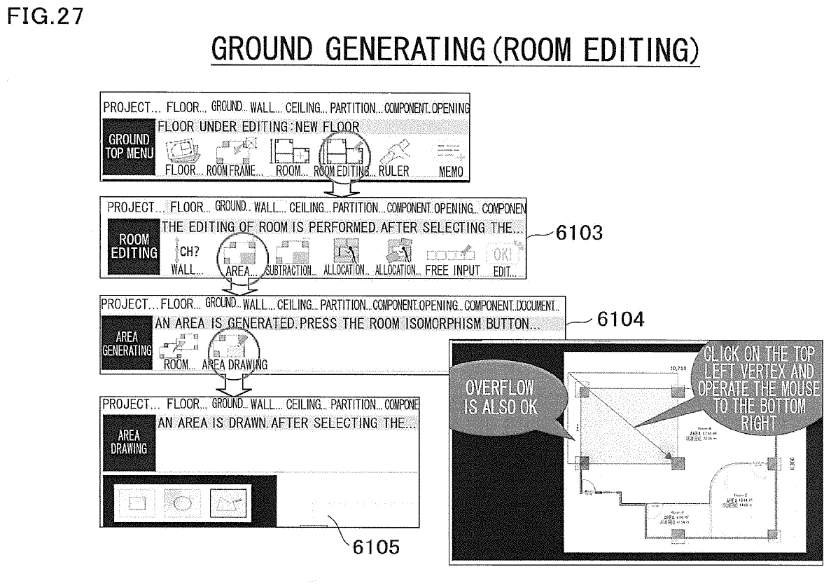

As shown in FIG. 27, when a room edit icon is operated, a room editing process for setting an “area” (construction area 21) for the entire room is performed. Specifically, the room edit icon is clicked to display a room edit display unit 6103. Then, an area generation icon displayed on the room edit display unit 6103 is clicked to display an area generation display unit 6104. The area generation display unit 6104 has a room isomorphism icon and an area drawing icon, and can perform generation by drawing mode processing of the selected icon.

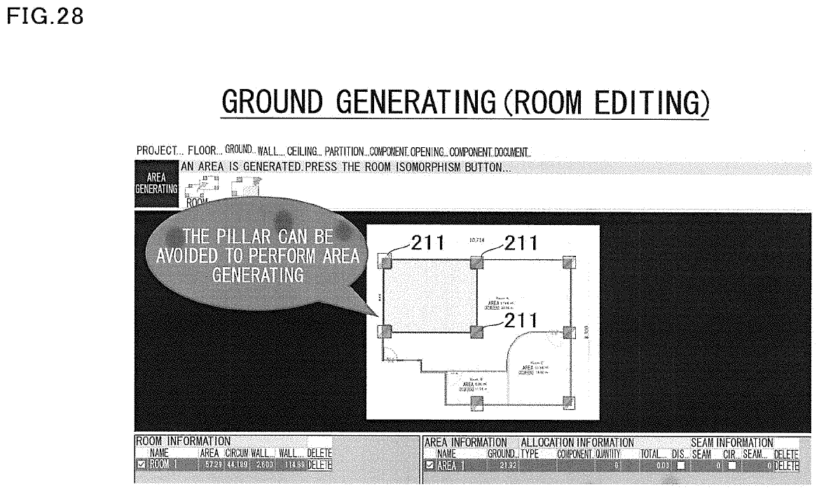

If an “area” that has the same shape as the room is selected, the room isomorphic icon is selected, and if an “area” that has a different shape from the room is selected, the area drawing icon is selected. When the area drawing icon is selected, an area drawing display unit 6105 appears, and a drawing process corresponding to any of a square icon, a circle icon, and a polygon icon can be selected. For example, if the drawing mode processing of the square icon is selected, the upper left vertex of the target “area” is clicked and the mouse is operated to the lower right. In addition, the upper left vertex may be located outside the “area”. When the red square shape is enlarged by the mouse operation and the “area” is surrounded by the square red line, the processing is terminated assuming that “area” is determined. At this time, as shown in FIG. 28, if a location such as a pillar where the building material 31 is not required to be allocated is assigned as the arrangement avoidance area 211, the square red line is drawn avoiding that location.

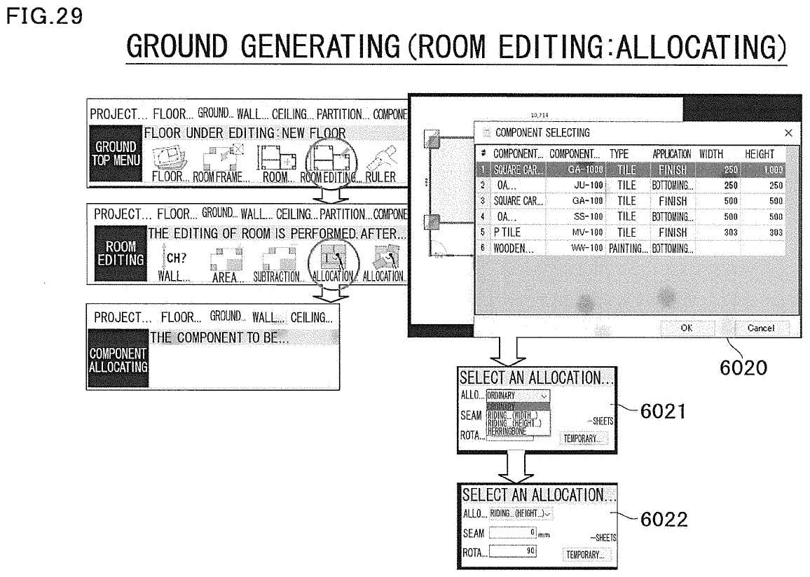

As shown in FIG. 29, when an allocation starting icon is operated, an allocating process for allocating ground materials to a range generated for “area” is performed. Specifically, when the allocation starting icon is clicked, a registered component master data display window 6020 appears. For example, when a 250×1,000 tile carpet is selected and an OK button is clicked, an allocation method selection window 6021 appears. The allocation method selection window 6021 displays an allocation method consisting of “normal”, “horse joint (width shift)”, “horse joint (height shift)”, and “herringbone” to be selected, and after any one of the allocation methods is selected, an allocation angle selection window 6022 appears.

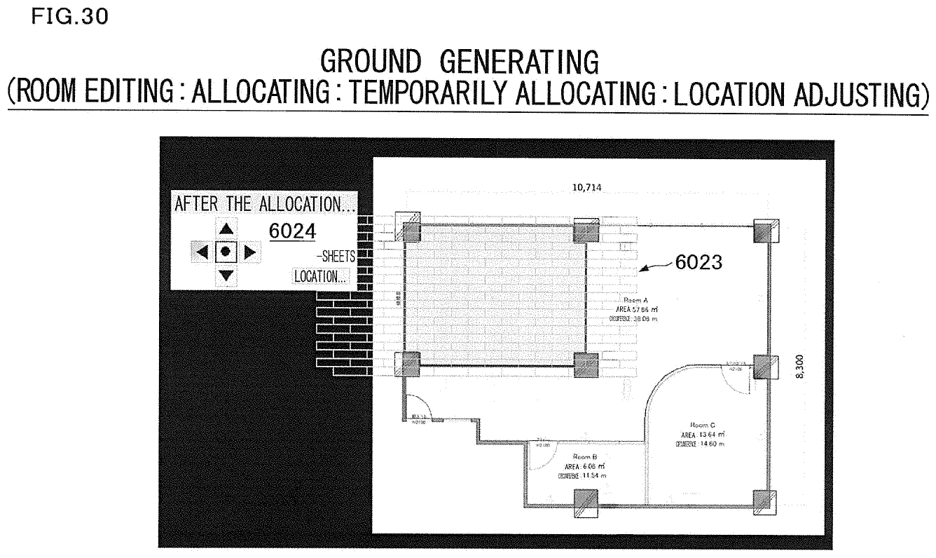

For example, if a “horse joint” is selected in the allocation method selection window 6021, “90 degree rotation” is input in the allocation angle selection window 6022, and a temporary allocation button is clicked, as shown in FIG. 30, a grid 6023 (building material group 3) corresponding to this allocation is displayed. In addition, a cross key window 6024 appears in the vicinity of the grid 6023, and when a cross key is clicked, the grid 6023 is moved in the vertical direction and in the horizontal direction, so that the overhang position can be moved.

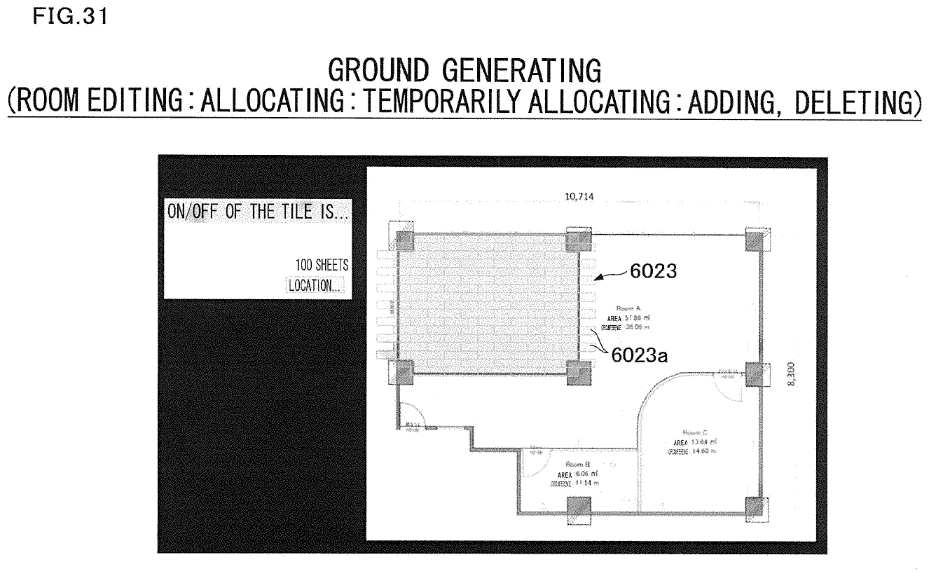

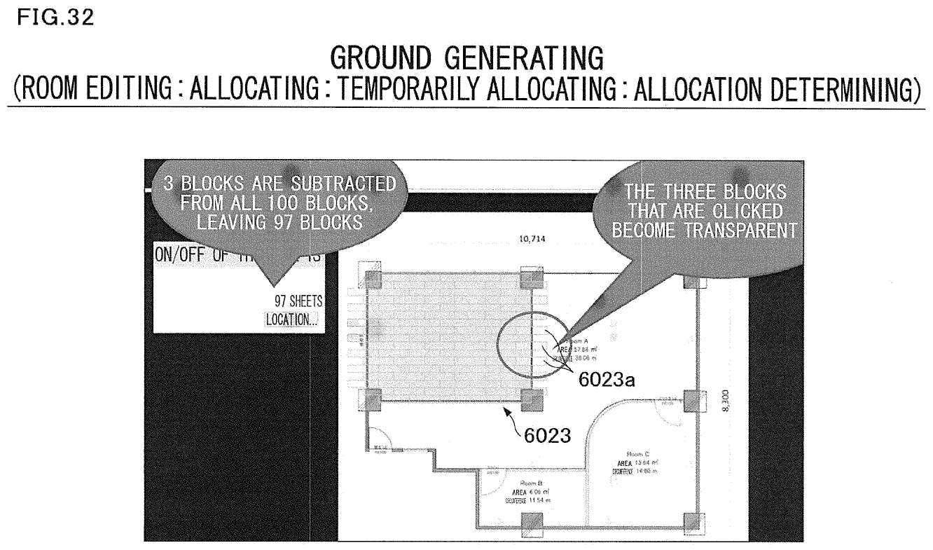

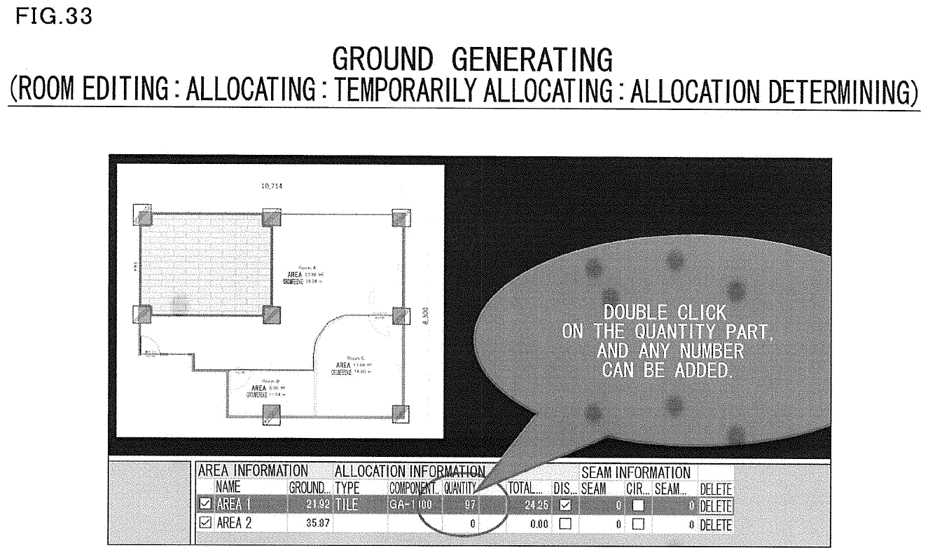

When a location determination button is clicked, as shown in FIG. 31, the total quantity (100 sheets) of the tile carpet 6023a at the overhang position at the time of clicking is displayed. Further, as shown in FIG. 32, regarding the tile carpet 6023a which is considered unnecessary, when the corresponding tile carpet 6023a is clicked, it is deleted from the grid 6023 and subtracted from the total quantity. In FIG. 33, when the tile carpets arranged at three positions are clicked, the tile carpets at the clicked positions are deleted, and the total quantity (97 sheets) obtained by subtracting the three sheets is displayed. When an allocation determination button is clicked after the arbitrary number subtraction is completed, the number information of tile carpets to which the allocation has been performed is added to the allocation information display unit arranged at the bottom of the screen. In addition, when a “quantity” display area in the allocation information display unit is double-clicked, an arbitrary number can be added.

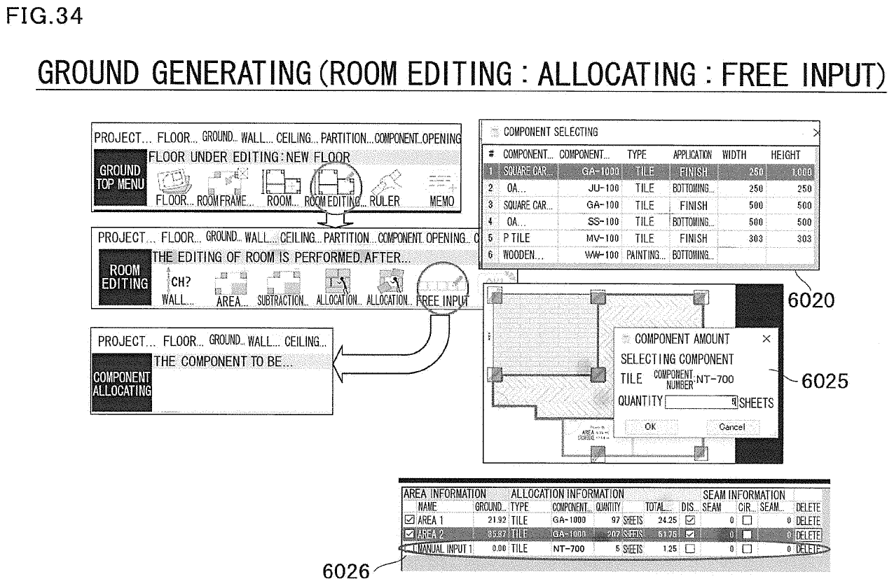

As shown in FIG. 34, when a free input icon is operated in room editing, a free input processing is performed. For example, when five sheets of 250×1,000 ground materials of different colors are required, the free input icon is clicked, a registered component master data display window 6020 appears, and the corresponding component is selected. When the corresponding component is selected, a quantity input screen window 6025 appears, and thus the required quantity is input and the OK button is clicked. As a result, the input data is added to the allocation information display unit 6026.

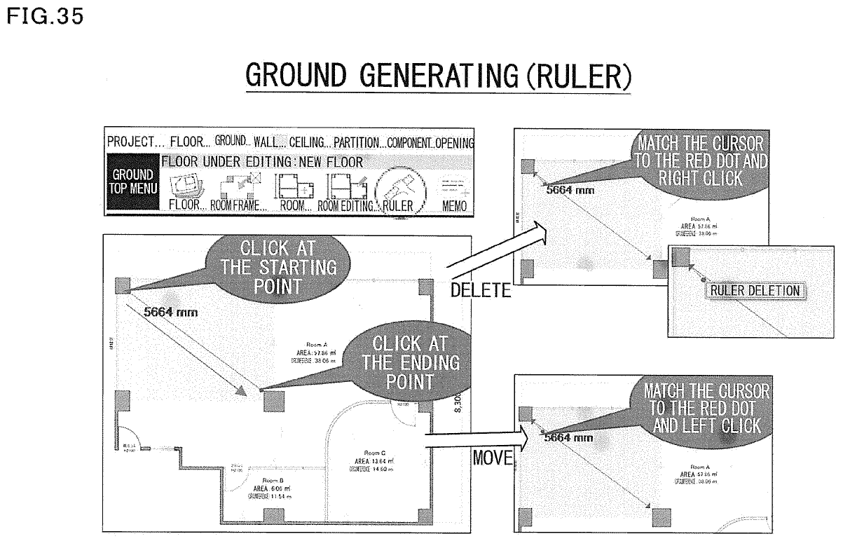

As shown in FIG. 35, when a ruler icon is operated, a ruler processing for obtaining a dimension from the starting point to the ending point in the diagram is performed. Specifically, a starting point on the diagram is clicked, the cursor is moved to the location to be measured with the mouse, and is clicked again. Thereby, the dimension between the starting point and the ending point is displayed. In addition, an intermediate point may exist between the starting point and the ending point. Thereby, for example, the length of the measurement target line of various shapes can be measured by arranging the intermediate point along the measurement target line such as a bent or curved wall. In addition, when deleting a numerical value once displayed, the deletion message is displayed by placing the cursor on the red circle portion drawn by the ruler and right-clicking, and the deletion is confirmed by clicking again. In addition, when moving the numerical value displayed on the ruler, the mouse is moved by operating the mouse while left-clicking at the red circle, and then the movement is confirmed by clicking again.

### (Specific Example of Building Material Estimation System: Partition Generating Process)

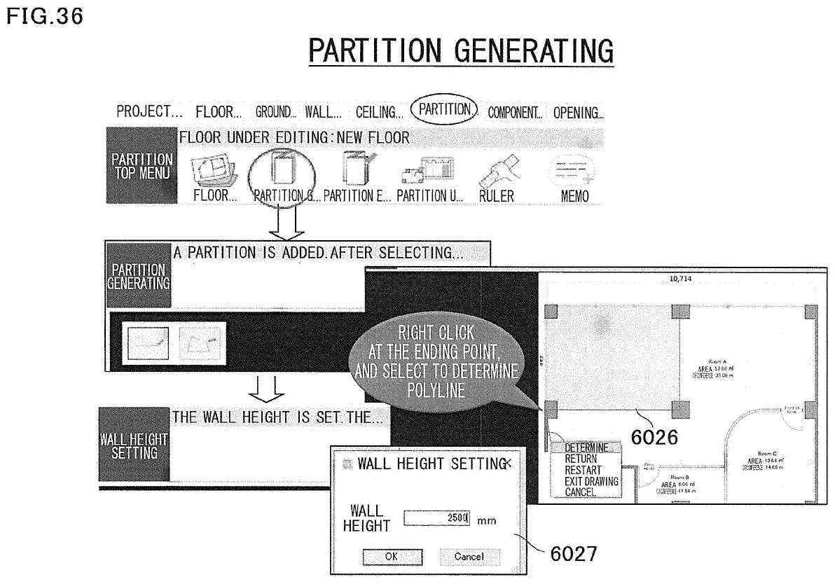

As shown in FIG. 36, when a partition generation tab is operated, a partition generating process is performed. Specifically, diagram data is reading in by the floor selecting process, and a partition generation icon is clicked. The partition generating can perform either straight line processing or polygon processing. In the case of generating by polygon processing, a polygonal line 6026 is generated from the starting point of the partition by a mouse operation, right-clicking is performed at the end point of the partition, and the polygonal line 6026 is determined. After selecting to determine the polygonal line, an OK button is clicked, and a wall height input screen window 6027 appears. When the wall height is input and the OK button is clicked, the partition information is displayed together with the partition display.

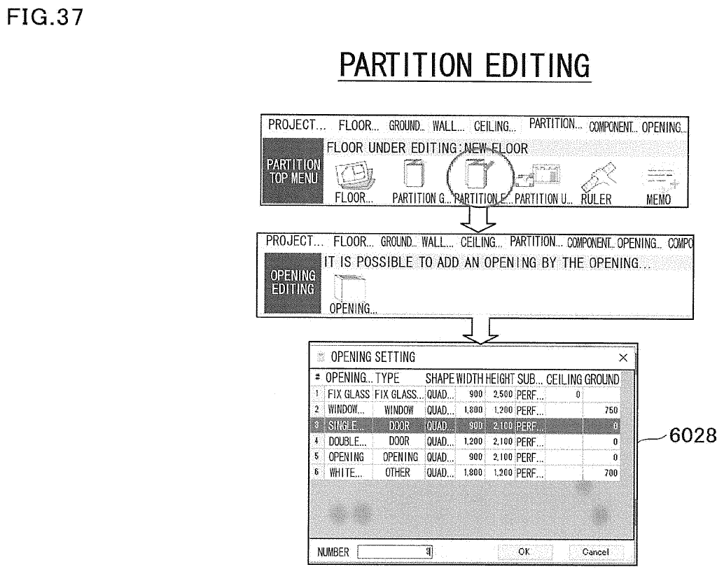

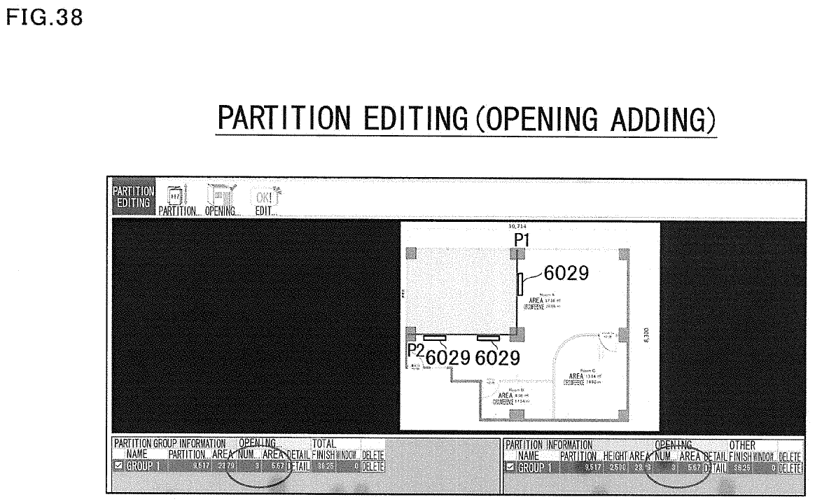

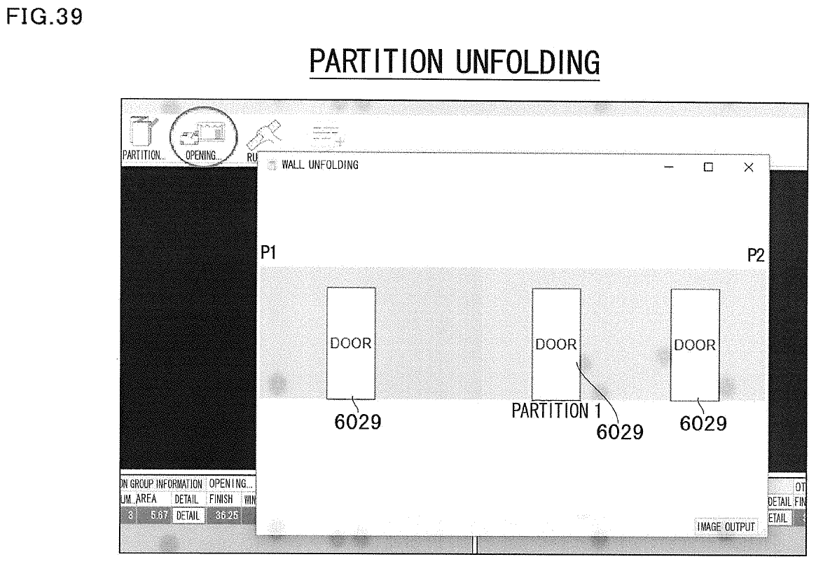

As shown in FIG. 37, when a partition edit icon is operated, a partition editing process for setting an opening (door, etc.) for the partition is performed. Specifically, when an opening edit icon is clicked and an opening addition icon displayed thereafter is clicked, an opening master data display window 6028 appears. Then, an opening master data to be added is selected, the number is input, and an OK button is clicked. Thereafter, as shown in FIG. 38, an opening icon 6029 displayed together with the number on the screen are moved by a mouse operation, and the opening icon is arranged by clicking on the corresponding part of the partition part. In addition, as shown in FIG. 39, when a partition unfolding icon is clicked, a partition unfolding view appears and the arrangement state of the partition can be confirmed. In addition, when the partition unfolding view is drawn from the drawing starting point P1 toward the drawing ending point P2, the right side of the drawing direction is the viewpoint position, so that it becomes an unfolding view toward a screen viewing direction from the upper left side to the wall direction.

### (Specific Example of Building Material Estimation System: Wall Generating Process: Room Editing Process)

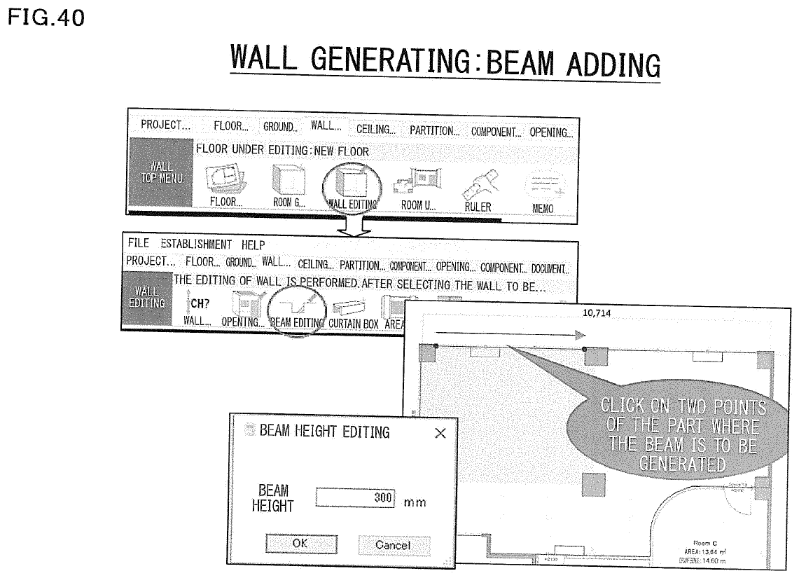

As shown in FIG. 40, when a wall generation tab is operated and then a wall edit icon is clicked, a wall editing process is performed. Specifically, after clicking the wall edit icon displayed in the wall editing process, two points of a place where a beam is to be set are clicked to display a beam height input screen window 6030. Then, the numerical value of the beam height is input. The same operation is repeated to add more beams. When an OK button is clicked after completing the beam generating, a yellow highlight line is displayed at the location where the beam was generated on the diagram, thereby enabling visual confirmation. In addition, FIG. 40 shows a case where ground information is taken over, but usually a beam is added after the wall is generated.

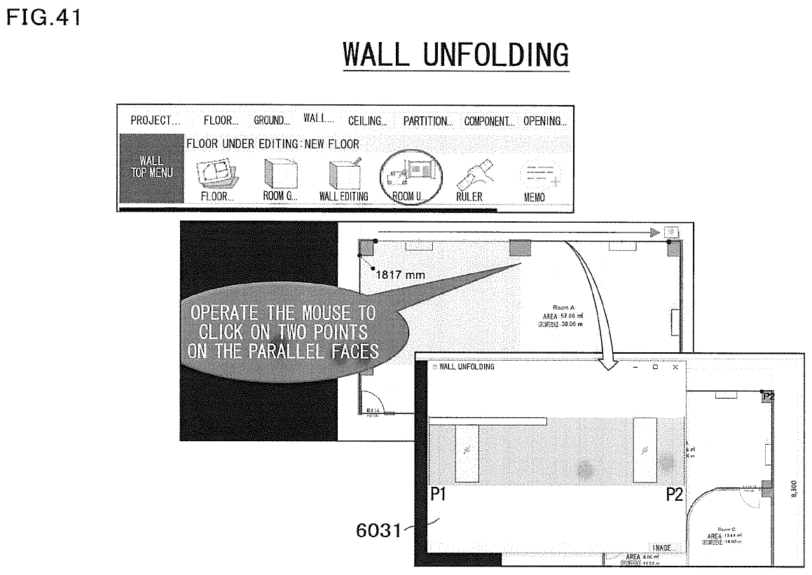

As shown in FIG. 41, when a wall unfolding icon is clicked, an unfolding process is performed. Specifically, after clicking the wall unfolding icon, two points on a parallel plane are clicked by operating the mouse, thereby causing an unfolding view window 6031 displaying an unfolded view between the two points to appear.

### (Specific Example of Building Material Estimation System: Ceiling Opening Editing Process)

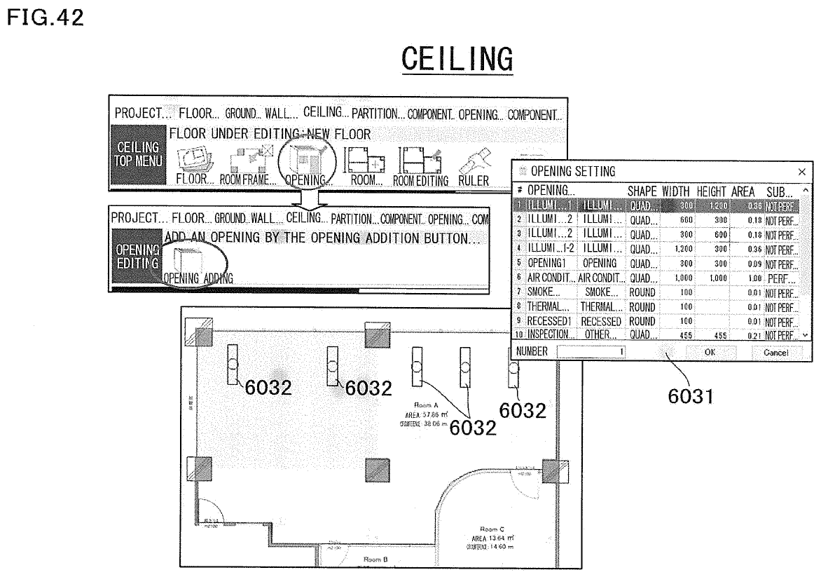

As shown in FIG. 42, when a ceiling generation tab is operated and then an opening edit icon is clicked, an opening editing process is performed. Specifically, the opening edit icon is clicked to start the opening editing process for setting an opening portion such as a lighting fixture or a gas sensor. When an opening addition icon is clicked, an opening master data display window 6031 appears, and the opening master data to be set is selected, the number is input, and then an OK button is clicked. Thereby, the selected opening icon 6032 and the number are displayed on the screen. Thereafter, a location to be configured on the diagram is clicked to complete the placement of the opening icon 6032.

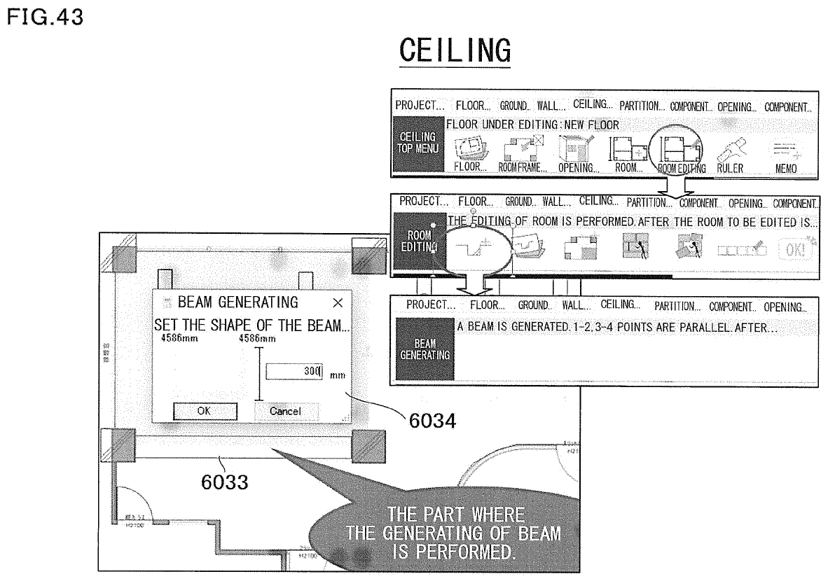

As shown in FIG. 43, when a beam generation icon is clicked in the opening editing process, a beam generating process is performed. Specifically, in the beam generation display, an explanation of “Generate a beam. Points 1-2 and 3-4 are parallel. After drawing, enter a beam height.” is displayed. According to this explanation, four points on the diagram are clicked to generate a beam 6033. That is, the beam 6033 in which the 1-2 point and the 3-4 point are parallel is displayed. Thereafter, a height input screen 6034 is displayed, and after the height is input, the beam 6033 is determined by clicking an OK button. When the beam 6033 is determined, a beam area is displayed, and is registered in the “beam list” as beam information and converted into master data. In addition, the beam area can be selected to be subtracted from the total area. In addition to clicking four points on the diagram, a beam width can be input by right-clicking.

The embodiments of the present invention have been described above, but only specific examples are illustrated, and the present invention is not particularly limited. Specific configurations of the respective means and the like can be appropriately changed in design. In addition, the effects described in the embodiments of the present invention are only the most preferable effects resulting from the present invention, and the effects of the present invention are not limited to those described in the embodiments of the present invention.

What is claimed is:

1. A building material estimation system, comprising:
a base diagram acquiring unit for acquiring a base diagram and storing the base diagram in a memory;
a construction area setting unit for setting a construction area in which building materials are arranged in the base diagram stored in the memory by operating an external device;
an avoidance assigning unit for assigning an arrangement avoidance area in which the building materials are not arranged in the construction area by operating the external device;
an arrangement diagram generating unit for unfolding a building material group in which the building materials are arranged in the memory, and generating a building material arrangement diagram which is formed in such a way that the building material group covers the construction area;
a display controlling unit for controlling a display device to display the building material arrangement diagram, the construction area, and the arrangement avoidance area in an overlapping manner;
a counting unit for obtaining the number of the building materials constituting the building material group in the building material arrangement diagram by determining the number of constructions of the building materials which at least overlap partially in the construction area and the number of avoidances of the building materials included completely in the arrangement avoidance area according to the building material group, the construction area, and the arrangement avoidance area unfolded in the memory and subtracting the number of avoidances from the number of constructions; and
an output unit for outputting the number of the building materials to an outside.

2. The building material estimation system according to claim 1, further comprising an editing unit for performing an editing process for relatively moving at least a part of the building material group in the building material arrangement diagram and the construction area displayed on the display device by operation of the external device.

3. The building material estimation system according to claim 1, further comprising an editing unit for performing an editing process for changing, by operation of the external device, with respect to the construction area, an angle of at least a part of the building material group in the building material arrangement diagram displayed on the display device.

4. The building material estimation system according to claim 1, further comprising an editing unit for performing an editing process for deleting at least a part of the building material group in the building material arrangement diagram displayed on the display device in a unit of a building material according to an assignment from the external device.

5. The building material estimation system according to claim 1, wherein the arrangement diagram generating unit generates a building material arrangement diagram in which the building materials are arranged in a herringbone arrangement.

6. A building material estimation method for determining the number of building materials to be arranged in a construction area of a building, comprising:
a step of base diagram acquiring for acquiring a base diagram and storing the base diagram in a memory;
a step of construction area setting for setting a construction area in which building materials are arranged in the base diagram stored in the memory by operating an external device;
a step of avoidance assigning for assigning an arrangement avoidance area in which the building materials are not arranged in the construction area by operating the external device;
a step of arrangement diagram generating for unfolding a building material group in which the building materials are arranged in the memory, and generating a building material arrangement diagram which is formed in such a way that the building material group covers the construction area;
a step of display controlling for controlling a display device to display the building material arrangement diagram, the construction area, and the arrangement avoidance area in an overlapping manner;
a step of counting for obtaining the number of the building materials constituting the building material group in the building material arrangement diagram by determining the number of constructions of the building materials which at least overlap partially in the construction area and the number of avoidances of the building materials included completely in the arrangement avoidance area according to the building material group, the construction area, and the arrangement avoidance area unfolded in the memory and subtracting the number of avoidances from the number of constructions; and
a step of output for outputting the number of the building materials to an outside.

7. A management server of a building material estimation system for obtaining the number of building materials to be arranged in a construction area of a building, comprising:
a memory for storing various data including data related to the number of the building materials; and
a controller,
wherein the controller performs:
a base diagram acquiring process for acquiring the base diagram and storing the base diagram in the memory;
a construction area setting process for setting a construction area in which building materials are arranged in the base diagram stored in the memory by operating an external device;
an avoidance assigning process for assigning an arrangement avoidance area in which the building materials are not arranged in the construction area by operating the external device;
an arrangement diagram generating process for unfolding a building material group in which the building materials are arranged in the memory, and generating a building material arrangement diagram which is formed in such a way that the building material group covers the construction area;
a display controlling process for controlling a display device to display the building material arrangement diagram, the construction area, and the arrangement avoidance area in an overlapping manner;
a counting process for obtaining the number of the building materials constituting the building material group in the building material arrangement diagram by determining the number of constructions of the building materials which at least overlap partially in the construction area and the number of avoidances of the building materials included completely in the arrangement avoidance area according to the building material group, the construction area, and the arrangement avoidance area unfolded in the memory and subtracting the number of avoidances from the number of constructions; and
an output process for outputting the number of the building materials to an outside.
